(19) United States
(12) Patent Application Publication
(10) Pub. No.: US 2025/0294813 A1
(43) Pub. Date: Sep. 18, 2025

(54) SEMICONDUCTOR DEVICE

(71) Applicant: Japan Display Inc., Tokyo (JP)

(72) Inventors: Akihiro HANADA, Tokyo (JP); Takuo KAITOH, Tokyo (JP); Motochika YUKAWA, Tokyo (JP)

(73) Assignee: Japan Display Inc., Tokyo (JP)

(21) Appl. No.: 19/078,407

(22) Filed: Mar. 13, 2025

(30) Foreign Application Priority Data
Mar. 14, 2024 (JP) 2024-040090

(51) Int. Cl. H10D 30/67; H10D 30/01

(52) U.S. Cl. CPC H10D 30/6755; H10D 30/031; H10D 30/6713; H10D 30/6734

(57) ABSTRACT

A semiconductor device includes an oxide insulating layer, a metal oxide layer having a first region and a second region arranged on the oxide insulating layer and spaced apart from each other, an oxide semiconductor layer arranged in contact with the first region and the second region, a gate insulating layer arranged to cover the oxide semiconductor layer, and a gate electrode arranged on the oxide semiconductor layer through the gate insulating layer, wherein the oxide semiconductor layer includes a channel region overlapping the gate electrode, a source region and a drain region sandwiching the channel region, and the channel region is in contact with the oxide insulating film between the first region and the second region.

### CROSS REFERENCE TO RELATED APPLICATIONS

This application claims the benefit of priority to Japanese Patent Application No. 2024-040090, filed on Mar. 14, 2024, the entire contents of which are incorporated herein by reference.

### FIELD

An embodiment of the present invention relates to a semiconductor device. In particular, an embodiment of the present invention relates to a semiconductor device used as a channel. In addition, an embodiment of the present invention relates to a method for manufacturing a semiconductor device.

### BACKGROUND

In recent years, a semiconductor device in which an oxide semiconductor is used for a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher mobility than the semiconductor device in which amorphous silicon is used for the channel.

It is essential to supply oxygen to an oxide semiconductor layer in the manufacturing process and to reduce the oxygen deficiencies formed in the oxide semiconductor layer in order for the semiconductor device in which the oxide semiconductor is used for the channel to perform a stable operation. For example, a technique of supplying oxygen to the oxide semiconductor layer is to cover the oxide semiconductor layer with an insulating layer formed under conditions that contain more oxygen, and then perform a thermal treatment.

### SUMMARY

A semiconductor device according to an embodiment of the present invention includes an oxide insulating layer, a metal oxide layer having a first region and a second region arranged on the oxide insulating layer and spaced apart from each other, an oxide semiconductor layer arranged in contact with the first region and the second region, a gate insulating layer arranged to cover the oxide semiconductor layer, and a gate electrode arranged on the oxide semiconductor layer through the gate insulating layer, wherein the oxide semiconductor layer includes a channel region overlapping the gate electrode, a source region and a drain region sandwiching the channel region, and the channel region is in contact with the oxide insulating film between the first region and the second region.

A semiconductor device according to an embodiment of the present invention includes an oxide insulating layer, a metal oxide layer having a first region and a second region that are provided on the oxide insulating layer and are separated from each other, and a third region provided between the first region and the second region, an oxide semiconductor layer arranged in contact with the metal oxide layer, a gate insulating layer arranged to cover the oxide semiconductor layer, and a gate electrode arranged on the oxide semiconductor layer through the gate insulating layer, wherein the oxide semiconductor layer includes a channel region overlapping the gate electrode, and a source region and a drain region sandwiching the channel region, the source region is in contact with the first region, the drain region is in contact with the second region, and the channel region is in contact with the third region, and a thickness of the metal oxide layer in the first region and the second region is larger than a thickness of the metal oxide layer in the third region.

### BRIEF DESCRIPTION OF DRAWINGS

FIG. 1 is a cross-sectional view showing an outline of a semiconductor device according to an embodiment of the present invention.

FIG. 2 is an enlarged view of a part of a semiconductor device shown in FIG. 1.

FIG. 3 is a plan view showing an outline of a semiconductor device according to an embodiment of the present invention.

FIG. 4 is a sequence diagram showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is an enlarged view of a part of a semiconductor device shown in FIG. 10.

FIG. 13 is a cross-sectional view showing an outline of a semiconductor device according to an embodiment of the present invention.

FIG. 14 is a cross-sectional view showing an outline of a semiconductor device according to an embodiment of the present invention.

FIG. 15 is a plan view showing an outline of a semiconductor device according to an embodiment of the present invention.

FIG. 16 is a cross-sectional view showing a method for manufacturing a semiconductor device according to an embodiment of the present invention.

FIG. 17 is a cross-sectional view showing an outline of a semiconductor device according to an embodiment of the present invention.

FIG. 18 is a cross-sectional view showing an outline of a semiconductor device according to an embodiment of the present invention.

FIG. 19 is an enlarged view of a part of a semiconductor device shown in FIG. 18.

FIG. 20 is a sequence diagram showing a method for manufacturing a semiconductor device according to an embodiment of the present invention.

FIG. 21 is a cross-sectional view showing a method for manufacturing a semiconductor device according to an embodiment of the present invention.

FIG. 22 is a cross-sectional view showing a method for manufacturing a semiconductor device according to an embodiment of the present invention.

FIG. 23 is a cross-sectional view showing an outline of a semiconductor device according to an embodiment of the present invention.

FIG. 24 is an enlarged view of a part of a semiconductor device shown in FIG. 23.

FIG. 25 is a sequence diagram showing a method for manufacturing a semiconductor device according to an embodiment of the present invention.

FIG. 26 is a cross-sectional view showing a method for manufacturing a semiconductor device according to an embodiment of the present invention.

FIG. 27 is a cross-sectional view showing a method for manufacturing a semiconductor device according to an embodiment of the present invention.

FIG. 28 is a cross-sectional view showing an outline of a semiconductor device according to an embodiment of the present invention.

FIG. 29 is a cross-sectional view showing an outline of a semiconductor device according to an embodiment of the present invention.

FIG. 30 is a sequence diagram showing a method for manufacturing a semiconductor device according to an embodiment of the present invention.

FIG. 31 is a sequence diagram showing a method for manufacturing a semiconductor device according to an embodiment of the present invention.

### DESCRIPTION OF EMBODIMENTS

When an oxide semiconductor layer is covered with an insulating layer formed under conditions that contain more oxygen and then heated, oxygen is supplied uniformly to the oxide semiconductor layer. This reduces the oxygen deficiencies in a channel region of the oxide semiconductor layer, which in turn suppresses abnormal transistor characteristics or characteristic fluctuations in reliability tests that occur when electrons originating from hydrogen are trapped in the defects. On the other hand, when the oxygen deficiencies in the source region and the drain region are reduced, the resistance of the source region and the drain region increases, which lowers the on-current of the transistor.

Therefore, an object of an embodiment of the present invention is to realize a semiconductor device which has high reliability and a high on-current.

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

“Semiconductor device” refers to all devices that can function by utilizing semiconductor characteristics. Transistors and semiconductor circuits region form of semiconductor device. For example, a semiconductor device may be used in an integrated circuit (IC) such as a micro-processing unit (MPU) or a memory circuit in addition to a transistor used in a display device.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer and an organic EL display device including an organic EL layer as the display device, the structure in the present embodiment can be applied to a display device including the other electro-optic layers described above.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Upward or downward refers to the stacking order in a structure with a plurality of layers. In addition, a planar view refers to viewing from a direction perpendicular to the surface of the substrate.

In the present specification, the terms “film” and “layer” can be used interchangeably.

The expressions “a includes A, B, or C”, “a includes any of A, B, and C”, and “a includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

### First Embodiment

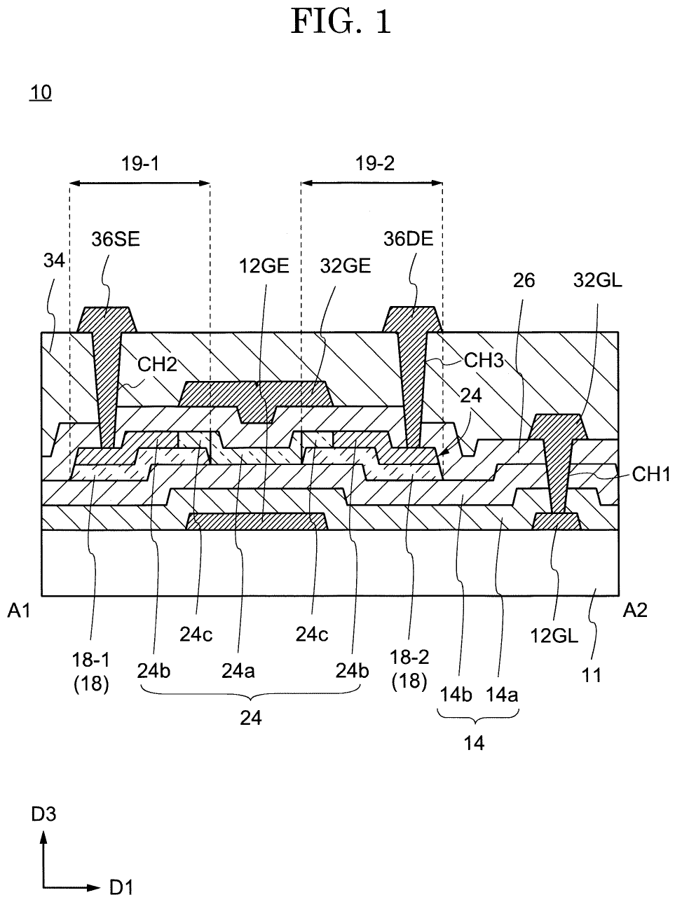

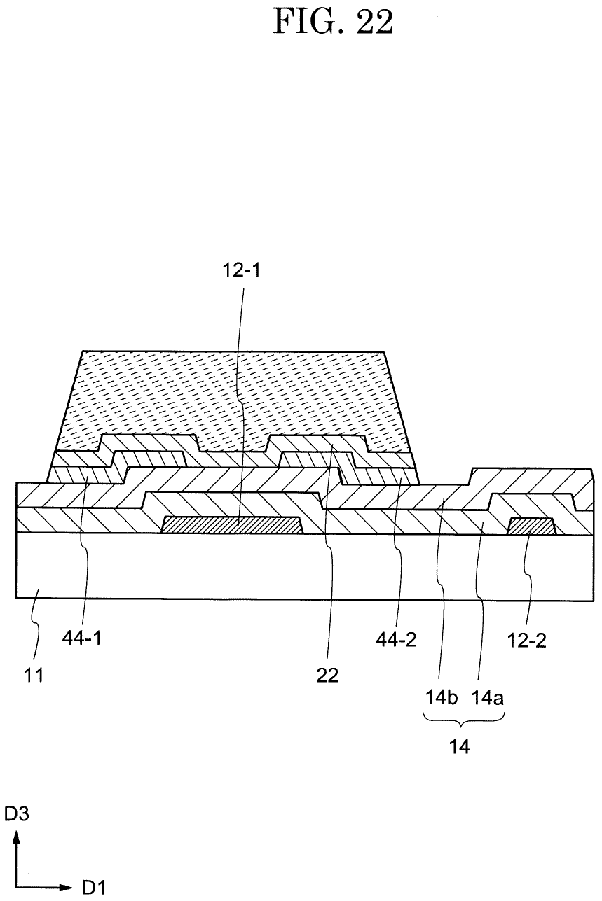

Semiconductor devices 10 to 10E according to an embodiment of the present invention will be described with reference to FIG. 1 to FIG. 22.

### [Configuration of Semiconductor Device 10]

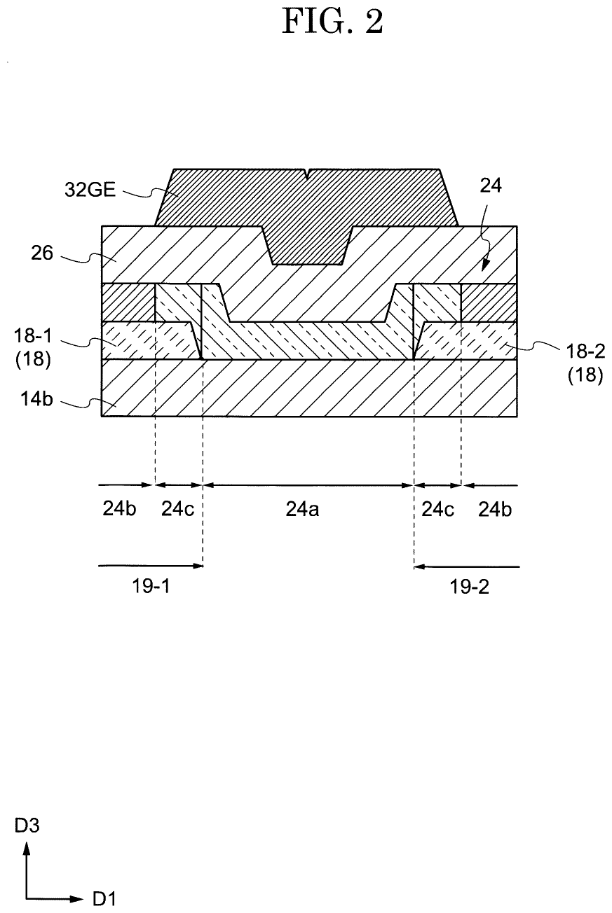

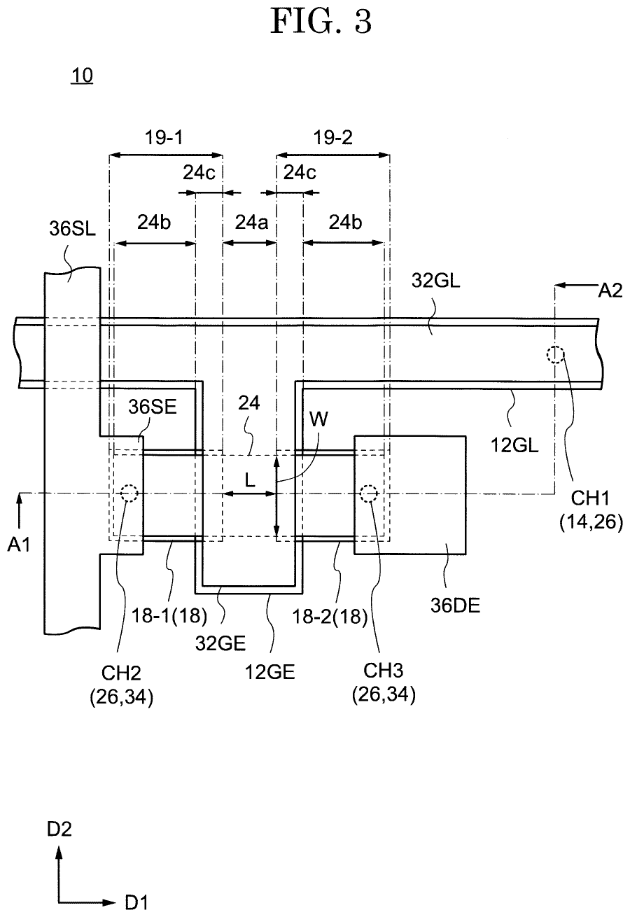

A configuration of the semiconductor device 10 according to an embodiment of the present invention will be described with reference to FIG. 1 to FIG. 3. FIG. 1 is a cross-sectional view showing an outline of a semiconductor device according to an embodiment of the present invention. FIG. 2 is an enlarged magnified view of a portion of a semiconductor device shown in FIG. 1. FIG. 3 is a plan view showing an outline of a semiconductor device according to an embodiment of the present invention. Also, the cross-section when cut by a single-dotted line in FIG. 3 corresponds to the cross-section in FIG. 1.

As shown in FIG. 1, the semiconductor device 10 is arranged above a substrate 11. The semiconductor device 10 includes at least an oxide insulating film 14b, a metal oxide layer 18-1 and 18-2, an oxide semiconductor layer 24, a gate insulating film 26, and a gate electrode 32GE. In some cases, the term “transistor” is used to refer to the oxide semiconductor layer 24, the gate insulating layer 26, and the gate electrode 32GE. The semiconductor device 10 may further include a gate electrode 12GE, a nitride insulating film 14a, an interlayer insulating film 34, a source electrode 36SE, and a drain electrode 36DE.

In this embodiment, a dual-gate transistor is used as the semiconductor device 10, with gate electrodes provided on both the upper and lower sides of the oxide semiconductor layer, but this is not limited to this configuration. For example, as the semiconductor device 10, a bottom-gate transistor in which the gate electrode is provided only below the oxide semiconductor layer, or a top-gate transistor in which the gate electrode is provided only above the oxide semiconductor layer, may be used. The above configuration is just one embodiment, and the present invention is not limited to the above configuration.

The gate electrode 12GE has a function of acting as a bottom gate for the semiconductor device 10 and as a light-shielding layer for the oxide semiconductor layer 24. A gate insulating film 14 has a function as a gate insulating film for the bottom gate. The gate insulating film 14 also has the nitride insulating film 14a and the oxide insulating film 14b. The nitride insulating film 14a has a function as a barrier film that shields impurities that diffuse from the substrate 11 to the oxide semiconductor layer 24. The oxide insulating film 14b has a function of releasing oxygen by a heating treatment in the manufacturing process.

A metal oxide layer 18 has a function of inhibiting the permeation of oxygen and hydrogen released from the adjacent insulating layer. For example, the metal oxide layer 18 is a layer that includes a metal oxide whose main component is aluminum. If a thickness of the metal oxide layer 18 is larger than at least 5 nm, the permeation of oxygen and hydrogen from the adjacent insulating layer can be inhibited. The metal oxide layer 18 has a first region 19-1 and a second region 19-2 that are separated from each other. The first region 19-1 and the second region 19-2 refer to the regions of the metal oxide layer 18 that are in contact with the oxide semiconductor layer 24. In FIG. 1 to FIG. 3, the metal oxide layer 18 includes the metal oxide layer 18-1, which includes the first region 19-1, and the metal oxide layer 18-2, which includes the second region 19-2.

The oxide semiconductor layer 24 is provided on the oxide insulating layer 14b and the metal oxide layers 18-1 and 18-2. The oxide semiconductor layer 24 is in contact with the oxide insulating layer 14b, the first region 19-1, and the second region 19-2. An edge of the oxide semiconductor layer 24 is approximately aligned with an edge of the metal oxide layer 18-1 and an edge of the metal oxide layer 18-2. In FIG. 1, a sidewall of the metal oxide layer 18 and a sidewall of the oxide semiconductor layer 24 are aligned in a straight line, but this configuration is not limited to this. An angle of the sidewall of the metal oxide layer 18 relative to the main surface of the substrate 11 may differ from an angle of the sidewall of the oxide semiconductor layer 24. The cross-sectional shape of at least one of the sidewalls of the metal oxide layer 18 and the oxide semiconductor layer 24 may be curved. The sidewalls of the metal oxide layer 18 and the oxide semiconductor layer 24 may not be aligned in a straight line.

The oxide semiconductor layer 24 has transparency. The oxide semiconductor layer 24 has a polycrystalline structure that includes multiple grains. As will be explained in more detail later, the oxide semiconductor layer 24 with a polycrystalline structure can be formed by using the Poly-OS (polycrystalline oxide semiconductor) technology. In the following, the composition of the oxide semiconductor layer 24 is explained, and the oxide semiconductor with a polycrystalline structure is sometimes referred to as Poly-OS.

The grain size of the grains of crystal contained in the Poly-OS observed from the top surface (or a thickness direction) of the oxide semiconductor layer 24 or a cross-section of the oxide semiconductor layer 24 is 0.1 μm or more, preferably 0.3 μm or more, and more preferably 0.5 μm or more. The crystal grain size can be obtained using methods such as cross-sectional SEM observation, cross-sectional TEM observation, or electron backscattered diffraction (EBSD).

A thickness of the oxide semiconductor layer 24 is larger than 10 nm and 30 nm or less. As mentioned above, the crystal grain size of the grains contained in the Poly-OS is 0.1 μm or more, so the oxide semiconductor layer 24 includes a region that contains only one crystal grain in the thickness direction.

As will be explained in more detail later, the oxide semiconductor layer 24 includes two or more metal elements, including indium, and a ratio of indium to the two or more metal elements is 50% or more. As metal elements other than indium, gallium (Ga), zinc (Zn), aluminum (Al), hafnium (Hf), yttrium (Y), zirconium (Zr), and lanthanide elements are used. Other metal elements may be used as the oxide semiconductor layer 24. Alternatively, an oxide semiconductor such as indium gallium zinc oxide (IGZO) may be used as the oxide semiconductor layer 24. The use of IGZO as the oxide semiconductor layer 24 is described in detail in a later modification.

The gate electrode 32GE functions as a top gate for the semiconductor device 10 and as a light-shielding layer for the oxide semiconductor layer 24. The gate insulating layer 26 functions as a gate insulating layer for the top gate and releases oxygen through a thermal treatment in the manufacturing process. The operation of the semiconductor device 10 is controlled mainly by the voltage supplied to the gate electrode 32GE. A supplementary voltage is supplied to the gate electrode 12GE. However, when the gate electrode 12GE is used simply as a light-shielding film, no specific voltage is supplied to the gate electrode 12GE, and the gate electrode 12GE may be in a floating state. In this case, the gate electrode 12GE may simply be referred to as a “light-shielding film”.

The interlayer insulating film 34 is formed on the gate insulating film 26 and the gate electrode 32GE. The interlayer insulating layer 34 has contact holes CH2 and CH3 that reach the oxide semiconductor layer 24. The source electrode 36SE is located inside the contact hole CH2, and the source electrode 36SE is in contact with the oxide semiconductor layer 24 at a bottom of the contact hole CH2. The drain electrode 36DE is located inside the contact hole CH3, and the drain electrode 36DE is in contact with the oxide semiconductor layer 24 at a bottom of the contact hole CH3.

In addition, the gate wiring 12GL, which is electrically connected to the gate electrode 12GE, is connected to the gate wiring 32GL, which is electrically connected to the gate electrode 32GE, via the contact hole CH1 provided in the gate insulating films 14 and 26.

In the semiconductor device 10, in the thermal treatment process of the manufacturing process, the top surface of the oxide semiconductor layer is affected by the process that occurs after the oxide semiconductor layer is formed (e.g., the patterning process or the etching process). This causes oxygen deficiencies to form on a surface of the oxide semiconductor layer. Oxygen deficiencies are likely to trap electrons originating from the hydrogen contained in the surrounding insulating layer. Therefore, when electrons are trapped in oxygen deficiencies, the resistance of the oxide semiconductor layer decreases. If the resistance of the oxide semiconductor layer decreases uniformly, the resistance of the channel region also decreases, and the transistor can no longer function.

Even if oxygen deficiencies are generated in the oxide semiconductor layer, if the oxygen deficiencies can be repaired in a subsequent thermal treatment, the resistance of the oxide semiconductor layer can be increased. For example, if the oxide semiconductor layer is covered with an insulating layer formed under conditions that contain more oxygen and then heated, oxygen is supplied uniformly to the oxide semiconductor layer. This reduces the oxygen deficiencies in the oxide semiconductor layer uniformly. By repairing the oxygen deficiencies in the channel region, the resistance can be increased. On the other hand, if the oxygen deficiencies in the source and drain regions are repaired, the resistance increases in the same way as in the channel region, which reduces the on-current of the transistor.

Therefore, in transistors that use an oxide semiconductor layer, it is necessary to promote the repair of oxygen deficiencies in the oxide semiconductor layer in a channel region, while suppressing the repair of oxygen deficiencies in the oxide semiconductor layer in the source and drain regions.

In the semiconductor device 10 according to an embodiment of the present invention, there is the metal oxide layer 18 including the first region 19-1 and the second region 19-2, which are provided on the oxide insulating layer 14b separated from each other, and the oxide semiconductor layer 24 on the oxide insulating layer 14b and the metal oxide layer 18. The gate electrode 32GE is provided to cover the space between the first region 19-1 and the second region 19-2.

As shown in FIG. 2, the oxide semiconductor layer 24 is divided into a first region 24a, a second region 24b, and a third region 24c. The first region 24a is a region of the oxide semiconductor layer 24 that is vertically below the gate electrode 32GE, and is a region that does not overlap with the metal oxide layer 18. In addition, the second region 24b is a region of the oxide semiconductor layer 24 that does not overlap with the gate electrode 32GE and is in contact with the metal oxide layer 18. The third region 24c is a region of the oxide semiconductor layer 24 that is vertically below the gate electrode 32GE and overlaps the metal oxide layers 18-1 and 18-2.

A thickness of the metal oxide layer 18 is at least larger than 5 nm, for example, larger than 5 nm and 50 nm or less, larger than 5 nm and 30 nm or less, and larger than 5 nm 20 nm or less, or larger than 5 nm and 10 nm or less. The thickness of the metal oxide layer 18 is at least larger than 5 nm, which suppresses the migration of oxygen and hydrogen from the neighboring insulating layer.

In the first region 24a, oxygen is supplied from both the oxide insulating layer 14b and the gate insulating layer 26 through a thermal treatment. This increases the resistance of the first region 24a, allowing it to function as a semiconductor. Therefore, the first region 24a can function as a channel region. The channel region is located between the first region 19-1 and the second region 19-2 of the metal oxide layer 18.

the second region 24b and the third region 34c are regions that are in contact with the metal oxide layers 18-1 and 18-2. In the second region 24b and the third region 34c, oxygen is supplied from the gate insulating layer 26 through a thermal treatment, but the transfer of oxygen from the oxide insulating layer 14b is suppressed by the metal oxide layers 18-1 and 18-2. Therefore, the resistance of the second region 24b and the third region 34c does not increase more than the first region 24a. In addition, oxygen deficiencies increase in the second region 24b due to the addition of impurity elements after the thermal treatment. The resistance of the second region 24b can be reduced by trapping electrons originating from hydrogen in the oxygen deficiencies. The second region 24b can be made to function as a source region and a drain region. The third region 24c does not have impurity elements added to it because it overlaps the gate electrode 32GE. Therefore, electrons originating from hydrogen are less likely to be trapped in oxygen deficiencies. As a result, the resistance of the third region 24c can be made lower than that of the first region 24a and higher than that of the second region 24b. Therefore, the third region 24c can be made to function like a LDD (Lightly Doped Drain) region.

The concentration of impurity elements contained in the second region 24b is preferably 1×10¹⁸ cm⁻³ or more and 1×10²¹ cm⁻³ or less when measured by a SIMS analysis (secondary ion mass spectrometry). Here, the impurity elements are argon (Ar), phosphorus (P), or boron (B). If the concentration in the second region 24b is 1×10¹⁸ cm⁻³ or more and 1×10²¹ cm⁻³ or less, it is presumed that the impurity elements were intentionally added by ion implantation or doping. However, the second region 24b may contain impurity elements other than argon (Ar), phosphorus (P), or boron (B) at a concentration of less than 1×10¹⁸ cm⁻³.

As shown in FIG. 3, in a plan view, the gate wiring 12GL and the gate wiring 32GL extend in the direction D1, and the gate electrode 12GE and the gate electrode 32GE extend in the direction D2. In addition, the source wiring SL extends in the direction D2. A planar pattern of the metal oxide layers 18-1 and 18-2 overlap a planar pattern of the oxide semiconductor layer 24. In the direction D1, a width of the gate electrode 12GE is larger than a width of the gate electrode 32GE. In addition, a width of the gate electrode 12GE and a width of the gate electrode 32GE in the direction D1 are larger than a length between the metal oxide layer 18-1 and the metal oxide layer 18-2. Here, a length between the metal oxide layer 18-1 and the metal oxide layer 18-2 is the same as the length of the first region 24a. In FIG. 3, a direction D1 is a direction connecting the source electrode SE and the drain electrode DE, and is the direction indicating a channel length L of the semiconductor device 10. Specifically, a channel length L is a length in the direction D1 in the first region 24a (channel region) where the oxide semiconductor layer 24 and the gate electrode 32GE overlap, and a channel width W is a length in the direction D2 of the first region 24a.

In the semiconductor device 10, the first region 24a of the oxide semiconductor layer 24, in which the channel region is formed, can have its resistance increased by supplying sufficient oxygen. On the other hand, by restricting the supply of oxygen to the second region 24b of the oxide semiconductor layer 24, which forms the source and drain regions of the transistor, the resistance can be reduced. This allows the resistance in the channel region and the resistance in the source and drain regions of the semiconductor device 10 to be controlled appropriately. As a result, good reliability test results can be obtained for the semiconductor device 10, and the on-current can be increased.

Here, reliability tests refer to, for example, NGBT (Negative Gate Bias-Temperature) stress tests, in which a negative voltage is applied to a gate, or PGBT (Positive Gate Bias-Temperature) stress tests, in which a positive voltage is applied to the gate. BT stress tests such as NGBT and PGBT are a type of accelerated test, and they can be used to evaluate the changes in transistor characteristics (ageing) that occur over long periods of use in a short period of time. In particular, the amount of change in the threshold voltage of the transistor before and after the BT stress test is an important indicator for examining reliability. The smaller the variation in threshold voltage before and after the BT stress test, the higher the reliability of the transistor.

In the semiconductor device 10 made using the above-mentioned manufacturing method, electrical characteristics with a mobility of 30 cm²/Vs or more, 35 cm²/Vs or more, or 40 cm²/Vs or more can be obtained in the range where the channel length L of the channel region is 2 μm or more and 4 μm or less, and the channel width of the channel region is 2 μm or more and 25 μm or less. The term “mobility” as used in this specification refers to the field-effect mobility in the saturation region of the semiconductor device 10, and means the maximum value of the field-effect mobility in the region where the potential difference (Vd) between the source electrode and the drain electrode is larger than the value (Vg-Vth) obtained by subtracting the threshold voltage (Vth) of the semiconductor device 10 from the voltage (Vg) supplied to the gate electrode.

### [Method for Manufacturing Semiconductor Device 10]

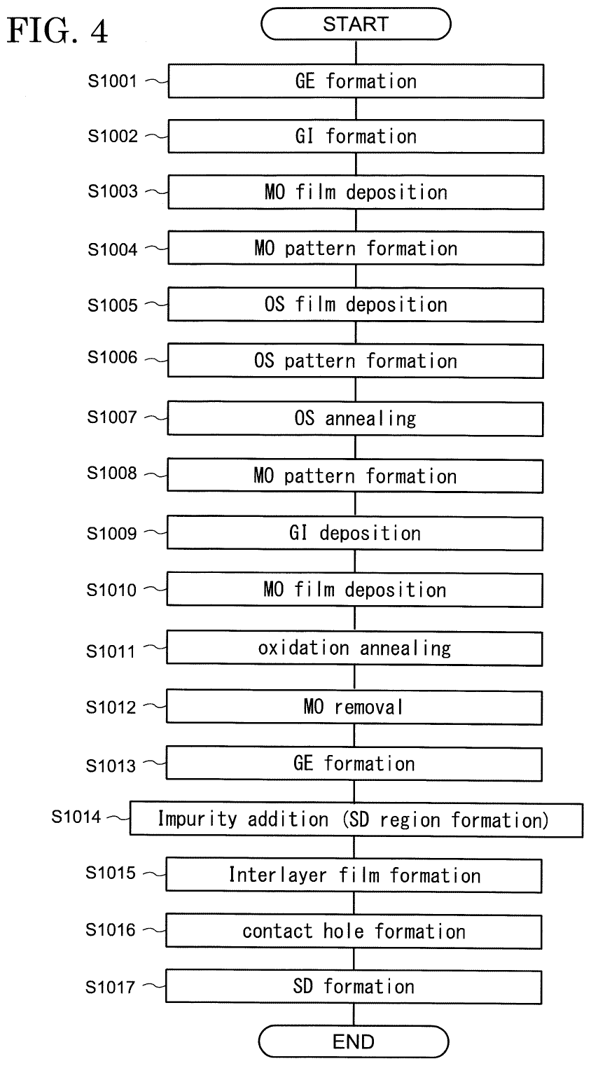

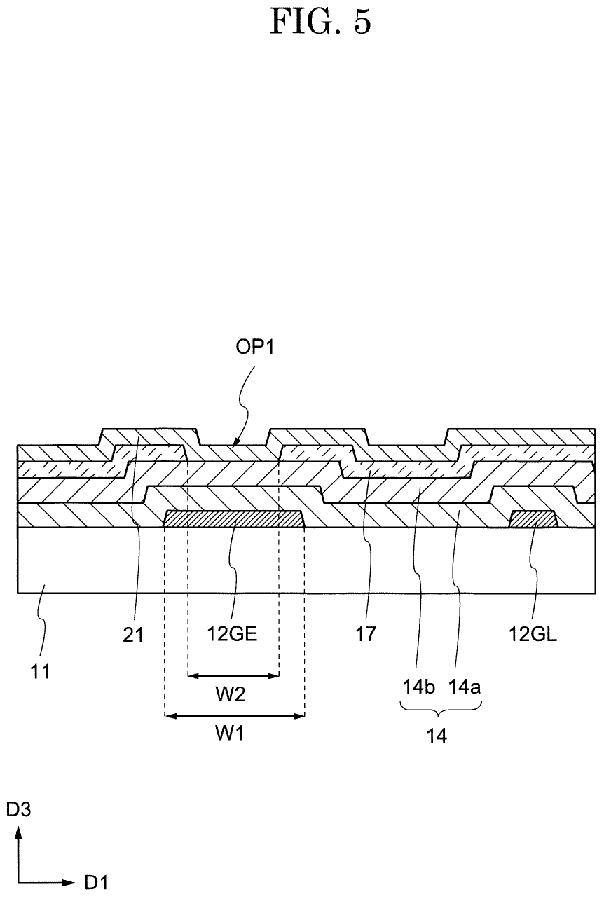

FIG. 4 to FIG. 10 are diagrams for be explaining a method for manufacturing the semiconductor device 10 according to an embodiment of the present invention. FIG. 4 is a sequence diagram showing a method for manufacturing the semiconductor device 10 according to an embodiment of the present invention. FIG. 5 to FIG. 10 are cross-sectional views showing a method for manufacturing the semiconductor device 10 according to an embodiment of the present invention.

As shown in FIG. 4 and FIG. 5, the gate electrode 12GE is formed on the substrate 11, and the gate insulating film 14 is formed on the gate electrode 12GE (see Step S1001 “GE formation” and S1002 “GI formation” in FIG. 4).

As the substrate 11, a rigid substrate with light transmissivity is used, such as a glass substrate, a quartz substrate, or a sapphire substrate. If the substrate 11 needs to be flexible, a substrate containing resin, such as a polyimide substrate, an acrylic substrate, a siloxane substrate, or a fluororesin substrate, is used as the substrate 11. When a substrate containing resin is used as the substrate 11, impurity elements may be introduced into the above-mentioned resin to improve the heat resistance of the substrate 11. When the semiconductor device 10 is used as an integrated circuit, a substrate that does not have light transmissivity, such as a semiconductor substrate such as a silicon substrate, a silicon carbide substrate, or a compound semiconductor substrate, or a conductive substrate such as a stainless steel substrate, may be used as the substrate 11.

The gate electrode 12GE is formed by processing the conductive film deposited by the sputtering method. Common metal materials are used as the gate electrode 12GE. For example, aluminum (AI), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds of these materials are used as the gate electrodes 12GE. The above materials may be used as a single layer or in a stacked layer as the gate electrode 12GE.

The gate insulating film 14 is formed by the chemical vapor deposition (CVD) method or the sputtering method. General insulating materials are used as the gate insulating film 14. For example, inorganic insulating materials such as silicon oxide (SiOₓ), silicon oxide nitride (SiOₓN_{y}), silicon nitride (SiNₓ), and silicon nitride oxide (SiNₓO_{y}) are used as the gate insulating film 14 in a single layer or as a multilayer. The above-mentioned SiOₓN_{y} is a silicon compound that contains nitrogen (N) in a ratio (x>y) lower than oxygen (O). SiNₓO_{y} is a silicon compound that contains oxygen in a ratio (x>y) lower than nitrogen.

In this embodiment, the gate insulating film 14 is formed using the nitride insulating film 14a and the oxide insulating film 14b. The nitride insulating film 14a is formed using, for example, silicon nitride. By using silicon nitride, impurities that diffuse from the substrate 11 towards the oxide semiconductor layer 24 can be blocked. The oxide insulating film 14b is formed using, for example, silicon oxide. By using silicon oxide, oxygen can be released by the thermal treatment. The temperature of the thermal treatment at which the insulating material containing oxygen releases oxygen is, for example, 500° C. or less, 450° C. or less, or 400° C. or less. In other words, silicon oxide releases oxygen at the thermal treatment temperature used in the manufacturing process of the semiconductor device 10 when a glass substrate is used as the substrate 11.

As shown in FIG. 4 and FIG. 5, a metal oxide film 17 is formed on the oxide insulating film 14b (step S1003 “MO film deposition” shown in FIG. 4). The metal oxide film 17 is formed by sputtering or atomic layer deposition (ALD).

As the metal oxide film 17, for example, a metal oxide with aluminum as the main component is used. For example, as the metal oxide film 17, inorganic insulating films such as aluminum oxide (AlOₓ), aluminum oxide nitride (AlOₓN_{y}), aluminum nitride oxide (AlNₓO_{y}), and aluminum nitride (AlNₓ) are used. A metal oxide film that has aluminum as its main component means that a ratio of aluminum contained in the metal oxide film is 1% or more of the entire metal oxide film 17. A ratio of aluminum contained in the metal oxide film 17 may be 5% or more and 70% or less, 10% or more and 60% or less, or 30% or more and 50% or less of the entire metal oxide film 17. The above ratios may be mass ratios or weight ratios. Alternatively, an oxide semiconductor such as indium gallium zinc oxide (IGZO) may be used as the metal oxide film 17. The use of IGZO as the metal oxide film 17 is described in detail in a later variant example.

A thickness of the metal oxide film 17 is, for example, larger than 5 nm, larger than 5 nm and 50 nm or less, larger than 5 nm and 30 nm or less, larger than 5 nm and 20 nm or less, or larger than 5 nm and 10 nm or less. In this embodiment a case where aluminum oxide is used as the metal oxide film 17 will be explained. Aluminum oxide has a high barrier property against gases such as oxygen or hydrogen. In other words, barrier properties refer to the function of preventing gases such as oxygen or hydrogen from penetrating the aluminum oxide. If a thickness of the metal oxide film 17 is larger than 5 nm, it has the effect of preventing gases such as oxygen or hydrogen from moving from the layer located beneath the aluminum oxide film to the layer located above the aluminum oxide film. Or, it has an effect of preventing gases such as oxygen or hydrogen from moving from the layer located above the aluminum oxide film to the layer located beneath the aluminum oxide film. On the other hand, if the thickness of the metal oxide film 17 is 5 nm or less, gases such as oxygen or hydrogen may permeate through it. In this embodiment, the aluminum oxide used as the metal oxide film 17 blocks the hydrogen and oxygen released from the oxide insulating film 14b, and prevents the released hydrogen and oxygen from reaching the oxide semiconductor layer that will be formed later.

As shown in FIG. 4 and FIG. 5, an opening OP1 is formed in the metal oxide film 17 (step S1004 “MO pattern formation” shown in FIG. 4). The opening OP1 in the metal oxide film 17 is formed in a region that overlaps the gate electrode 12GE. Although not shown in the figure, the opening OP1 is formed so that it is parallel to the direction in which the gate electrode 12GE extends. The opening OP1 can be formed, for example, by wet etching using hydrofluoric acid. In the semiconductor device 10, a width W2 (length in the direction D1) of the opening OP1 is smaller than the width W1 of the gate electrode 12GE. The width W2 (length in the D1 direction) of the opening OP1 is equivalent to the channel length L of the channel region to be formed later. In addition, the length (length in the direction D2) of the opening OP1 is preferably longer than the width (length in the direction D2) of the oxide semiconductor layer 24 to be formed later.

Next, as shown in FIG. 4 and FIG. 5, an oxide semiconductor film 21 is formed on the metal oxide film 17 (step S1005 “OS film deposition” shown in FIG. 4). The oxide semiconductor layer 21 is formed by sputtering or atomic layer deposition (ALD). A thickness of the oxide semiconductor layer 21 is, for example, larger than 10 nm and 30 nm or less.

As the oxide semiconductor film 21, a metal oxide having semiconductor characteristics can be used. As the oxide semiconductor film 21, for example, an oxide semiconductor containing two or more metal elements including indium (In) is used. In addition, the ratio of indium to the two or more metal elements contained in the oxide semiconductor is 50% or more. In addition to the indium element, gallium (Ga), zinc (Zn), aluminum (Al), hafnium (Hf), yttrium (Y), zirconium (Zr), or lanthanide elements are used as the oxide semiconductor film 21. Elements other than those listed above may be used as the oxide semiconductor film 21. Alternatively, an oxide semiconductor such as indium gallium zinc oxide (IGZO) may be used as the oxide semiconductor film 21 (oxide semiconductor layer 24). The use of IGZO as the oxide semiconductor film 21 is described in detail in a later variant example.

When using the oxide semiconductor film 21 with the ratio of 50% or more of indium in two or more metal elements, it is preferable that the oxide semiconductor film 21 is amorphous (a state with a small amount of crystalline component of the oxide semiconductor) after film formation and before OS annealing. In other words, the method of forming the oxide semiconductor film 21 should be such that the oxide semiconductor film 21 immediately after forming is not crystallized as much as possible. For example, when the oxide semiconductor film 21 is formed by the sputtering method, the oxide semiconductor film 21 is formed while controlling the temperature of the object to be coated (the substrate 11 and the structure formed thereon).

When a film is deposited on a substrate using the sputtering method, the temperature of the substrate rises during the deposition process because the ions generated in the plasma and the atoms that are recoiled by the sputtering target collide with the substrate. When the temperature of the substrate increases during the film deposition process, the oxide semiconductor film 21 will contain microcrystals immediately after the film deposition process. If the oxide semiconductor film 21 contains microcrystals, it will not be possible to increase the crystal grain size by subsequent OS annealing. In order to control the temperature of the substrate as described above, for example, the film deposition process can be performed while cooling the substrate. For example, the temperature of the substrate surface to be deposited (hereinafter referred to as the “deposition temperature”) can be cooled from the side opposite the surface to be coated so that the temperature of the surface to be coated (hereinafter referred to as the “coating temperature”) is 100° C. or less, 70° C. or less, 50° C. or less, or 30° C. or less. In particular, it is preferable that the coating temperature of the oxide semiconductor film 21 in this embodiment is 50° C. or less. By forming the oxide semiconductor film 21 while cooling the substrate, it is possible to obtain an oxide semiconductor film 21 with a low crystal component content immediately after the film is formed. In this embodiment, the oxide semiconductor film 21 is formed at a film formation temperature of 50° C. or less, and the OS annealing described below is performed at a heating temperature of 400° C. or more. In this embodiment, it is preferable that the difference between the temperature at which the oxide semiconductor film 21 is formed and the temperature at which the OS annealing is performed on the oxide semiconductor film 21 is 350° C. or more.

In the sputtering process, an amorphous oxide semiconductor film 21 is formed under conditions where the oxygen partial pressure is 10% or less. If the oxygen partial pressure is high, the excess oxygen contained in the oxide semiconductor film 21 causes the oxide semiconductor film 21 to contain microcrystals immediately after it is formed. Therefore, it is preferable to form the oxide semiconductor film 21 under conditions where the oxygen partial pressure is low. The oxygen partial pressure is, for example, 3% or more and 5% or less, and preferably 3% or more and 4% or less. If an oxide semiconductor film is deposited under conditions of an oxygen partial pressure of 2%, the oxide semiconductor film will not crystallize even if an OS annealing process is subsequently performed.

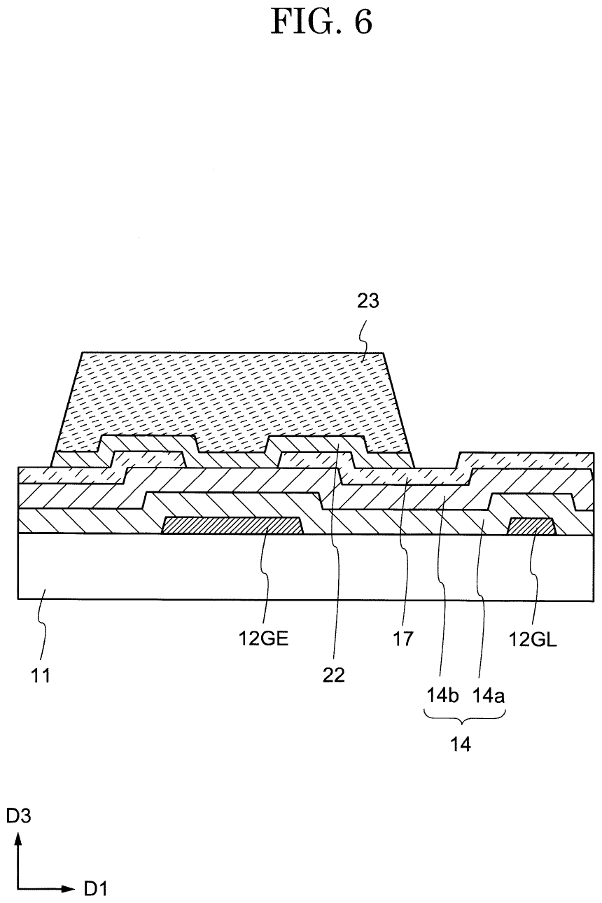

As shown in FIG. 4 and FIG. 6, a pattern is formed in the oxide semiconductor layer 22 (step S1006 “OS pattern formation” shown in FIG. 4). A resist mask 23 is formed on the oxide semiconductor layer 21, and the oxide semiconductor layer 21 is etched using the resist mask 23. Wet etching or dry etching may be used to etch the oxide semiconductor layer 21. Wet etching may be performed using an acidic etchant. For example, oxalic acid, PAN, sulfuric acid, hydrogen peroxide, or hydrofluoric acid can be used as the etchant. This allows a patterned oxide semiconductor layer 22 to be formed. The resist mask 23 is then removed.

It is preferable that the oxide semiconductor film 21 is patterned before the OS annealing. When the oxide semiconductor film 21 is crystallized by the OS annealing, it tends to be difficult to etch. Even if damage occurs to the patterned oxide semiconductor layer 22 due to etching, it is preferable because the damage to the oxide semiconductor layer 22 can be repaired by the OS annealing performed in step S1007 later.

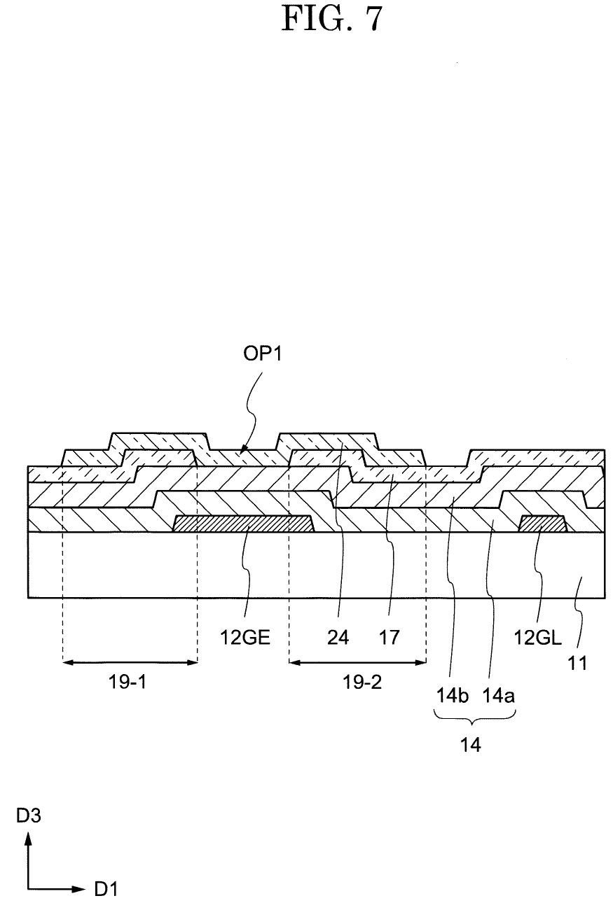

As shown in FIG. 4 and FIG. 7, after patterning the oxide semiconductor layer 22, a thermal treatment (OS annealing) is performed on the oxide semiconductor layer 22 (step S1007 “OS annealing” shown in FIG. 4). In the OS annealing, the oxide semiconductor layer 22 is held at a predetermined temperature for a predetermined time. The predetermined temperature is 300° C. or more and 500° C. or less, and preferably 350° C. or more and 450° C. or less. The holding time at the predetermined temperature is 15 minutes or more and 120 minutes or less, and preferably 30 minutes or more and 60 minutes or less. By performing the OS annealing, the oxide semiconductor layer 22 is crystallized, and the oxide semiconductor layer 24 having a polycrystalline structure is formed.

In this embodiment, the oxide semiconductor film 21 is formed by sputtering at a low oxygen partial pressure of 3% or more and 5% or less. By forming the oxide semiconductor film 21 under conditions of low oxygen partial pressure, it is possible to suppress the inclusion of excess oxygen in the oxide semiconductor film 21 and to suppress the inclusion of microcrystals in the oxide semiconductor film 21 immediately after formation. This makes it possible to suppress the growth of crystals from microcrystals during the thermal treatment of the oxide semiconductor layer 22. Therefore, even if the oxide semiconductor film 21 is formed with a thin film thickness of 10 nm or larger but 30 nm or less, the crystal grain size of the polycrystalline structure of the oxide semiconductor layer 22 can be increased.

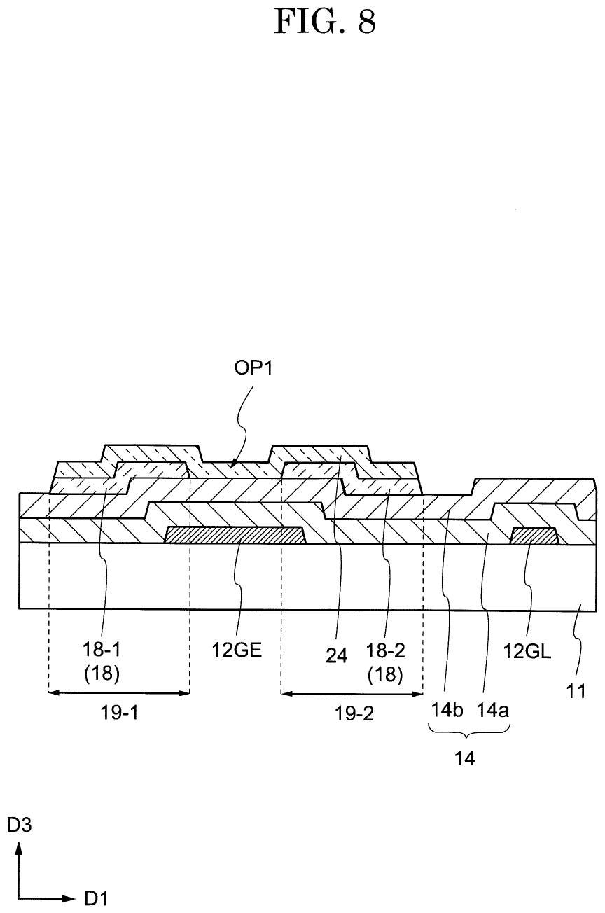

As shown in FIG. 4 and FIG. 8, the metal oxide film 17 is patterned to form the metal oxide layer 18-1 having the first region 19-1 and the metal oxide layer 18-2 having the second region 19-2 (step S1008 “MO pattern formation” shown in FIG. 4). The oxide semiconductor layer 24, which has been sufficiently crystallized by a thermal treatment, has high etching resistance. Therefore, when patterning the metal oxide film 17 using the crystallized oxide semiconductor layer 24 as a mask, it is possible to suppress the disappearance of the oxide semiconductor layer 24. The metal oxide film 17 is etched using the oxide semiconductor layer 24, which has been polycrystallized in the above process, as a mask. As a result, the sidewalls of the metal oxide layer 18-1 and the sidewalls of the metal oxide layer 18-2 are aligned in a straight line with the sidewalls of the oxide semiconductor layer 24. Wet etching may be used to etch the metal oxide film 17, or dry etching may be used. Dilute hydrofluoric acid (DHF) may be used as the wet etching agent. By etching the metal oxide film 17 using the oxide semiconductor layer 24 as a mask, the photolithography process may be omitted. In this embodiment, as shown in FIG. 3, a length of the opening OP1 in the metal oxide film 17 in the direction D2 is longer than a length of the channel width W of the oxide semiconductor layer. In this state, by etching the metal oxide film 17, the metal oxide film 17 can be separated into the metal oxide layer 18-1 including the first region 19-1 and the metal oxide layer 18-2 including the second region 19-2.

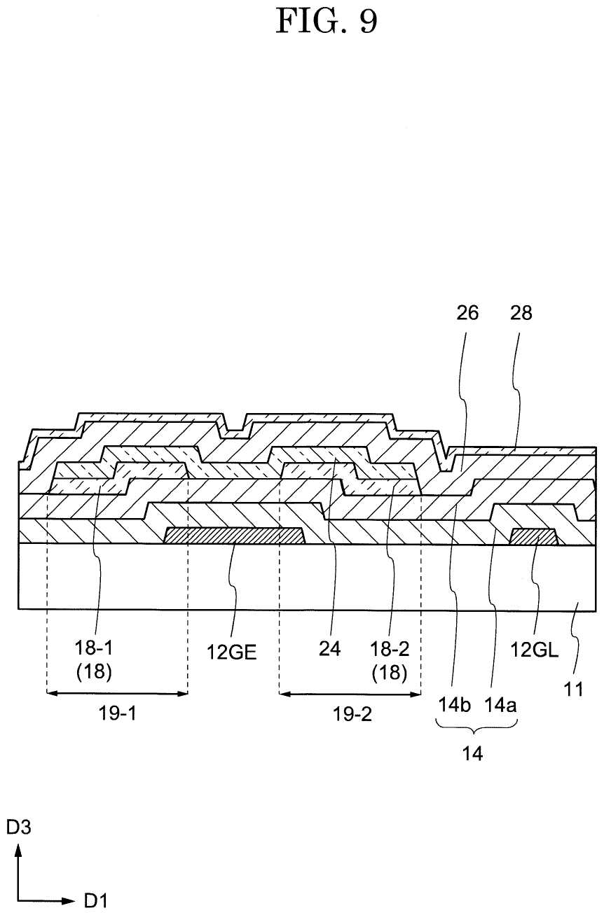

As shown in FIG. 4 and FIG. 9, the gate insulating film 26 is formed on the oxide semiconductor layer 24 (step S1009 “GI deposition” shown in FIG. 4). A thickness of the gate insulating film 26 is, for example, 50 nm or more and 300 nm or less, 60 nm or more and 200 nm or less, or 70 nm or more and 150 nm or less.

It is preferable to use an insulating material containing oxygen as the gate insulating film 26. In addition, it is preferable to use an insulating film with few defects as the gate insulating film 26. For example, when comparing the composition ratio of oxygen in the gate insulating film 26 with a composition ratio of oxygen in an insulating film with a composition similar to that of the gate insulating film 26 (hereinafter referred to as “other insulating film”), the composition ratio of oxygen in the gate insulating film 26 is closer to the stoichiometric ratio of the insulating film than the composition ratio of oxygen in the other insulating film. For example, when silicon oxide (SiOₓ) is used for both the gate insulating film 26 and the oxide insulating film 14b, the oxygen composition ratio of the silicon oxide used for the gate insulating film 26 is closer to the stoichiometric ratio of silicon oxide than the oxygen composition ratio of the silicon oxide used for the interlayer insulating film 34. For example, a layer that does not show any defects when evaluated using electron spin resonance (ESR) may be used as the gate insulating film 26.

In order to form the gate insulating film 26 with few defects, the gate insulating film 26 may be formed at a film formation temperature of 350° C. or higher. In addition, after the gate insulating film 26 is formed, a process of implanting oxygen into a part of the gate insulating film 26 may be performed. In this embodiment, in order to form the gate insulating film 26 with few defects, silicon oxide is formed at a film formation temperature of 350° C. or higher.

As shown in FIG. 4 and FIG. 9, a metal oxide film 28 is formed on the gate insulating film 26 (step S1010 “MO film deposition” shown in FIG. 4). For the material and deposition method of the metal oxide film 28, it is sufficient to refer to the material and deposition method described for the metal oxide film 17. In addition, a thickness of the metal oxide film 28 is sufficient if it is larger than 5 nm, for example, larger than 5 nm and less than 50 nm, larger than 5 nm and less than 30 nm, larger than 5 nm and less than 20 nm, or larger than 5 nm and less than 10 nm.

As shown in FIG. 4 and FIG. 9, a thermal treatment (oxidation annealing) is performed to supply oxygen to the oxide semiconductor layer 24 while the gate insulating layer 26 and the metal oxide film 28 are deposited on the oxide semiconductor layer 24 (step S1011 “oxidation annealing” shown in FIG. 4).

In this embodiment, the oxide semiconductor layer 24 uses an oxide semiconductor that contains two or more metals, including indium (In), and the ratio of indium in the two or more metals is 50% or more. Oxide semiconductors with a high indium ratio tend to crystallize easily, but the oxygen contained in the oxide semiconductor layer is easily reduced, and oxygen deficiencies tend to form.

In addition, a top surface of the oxide semiconductor layer 22 is affected by the processes (e.g., patterning or etching) that are performed after the oxide semiconductor layer 22 is formed. On the other hand, a bottom surface of the oxide semiconductor layer 22 (a side of the oxide semiconductor layer 22 facing the substrate 11) is less susceptible to the above-mentioned effects.

Therefore, a number of oxygen deficiencies formed on the top surface of the oxide semiconductor layer 22 is greater than the number of oxygen deficiencies formed on the bottom surface of the oxide semiconductor layer 22. In other words, the oxygen deficiencies in the oxide semiconductor layer 22 do not exist uniformly in a thickness direction of the oxide semiconductor layer 22, but rather exist in an uneven distribution in the thickness direction of the oxide semiconductor layer 22. Specifically, the oxygen deficiencies in the oxide semiconductor layer 22 are less on the bottom surface side of the oxide semiconductor layer 22 and more on the top surface side of the oxide semiconductor layer 22.

When a uniform oxygen supply process is applied to the oxide semiconductor layer 22 with an oxygen deficiency distribution as described above, if the amount of oxygen necessary to repair the oxygen deficiencies formed on the top surface of the oxide semiconductor layer 22 is supplied, an excess of oxygen is supplied to the bottom surface of the oxide semiconductor layer 22. As a result, on the bottom surface, a defect level different from the oxygen deficiency is formed due to the excess oxygen, and phenomena such as characteristic fluctuations in reliability tests or a decrease in field effect mobility occur. Therefore, in order to suppress such phenomena, it is necessary to supply oxygen to the top surface of the oxide semiconductor layer 22 while suppressing the supply of oxygen to the bottom surface of the oxide semiconductor layer 22.

As mentioned above, it is preferable that oxygen deficiencies are repaired in the channel region of the transistor compared to the source and drain regions.

The oxygen released from the gate insulating film 26 and the oxide insulating film 14b is blocked by the metal oxide film 28. As a result, the top surface and sides of the oxide semiconductor layer 24 are supplied with oxygen released from the gate insulating film 26 and the oxide insulating film 14b. As a result, the oxygen deficiency on the top surface and sides of the oxide semiconductor layer 24 is reduced. The oxygen released from the oxide insulating layer 14b is blocked by the metal oxide layers 18-1 and 18-2, but is supplied to the first region 24a of the oxide semiconductor layer 24 that is in contact with the oxide insulating layer 14b. This reduces the oxygen deficiency in the first region 24a of the oxide semiconductor layer 24 that is in contact with the oxide insulating layer 14b. In addition, in the bottom surface of the oxide semiconductor layer 24, there are regions where the supply of oxygen is suppressed and regions where oxygen is supplied. In this way, by providing metal oxide layers 18-1 and 18-2 that are separated from each other under the oxide semiconductor layer 24, it is possible to control the regions where oxygen deficiencies are repaired. After the oxidation annealing, the metal oxide film 28 is removed (step S1012 “MO removal” shown in FIG. 4). At this point, the contact hole CH1 is formed in the gate insulating films 14 and 16, in order to connect the gate wiring 32GL and the gate wiring 12GL that will be formed in the next process.

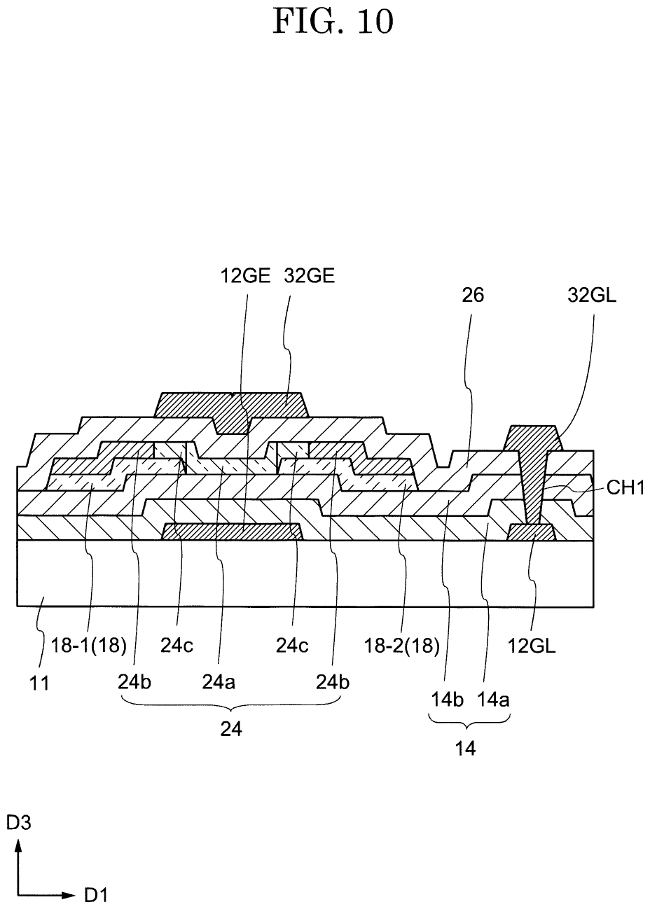

Next, as shown in FIG. 4 and FIG. 10, the gate electrode 32GE is formed on the gate insulating film 26 (step S1013 “GE formation” shown in FIG. 4).

The gate electrode 32GE is formed by processing a conductive film deposited by a sputtering method. As the gate electrode 32GE, general metal materials are used in the same way as the gate electrode 12GE. For information on the materials that can be used for the gate electrode 32GE, please refer to the description of the materials for the gate electrode 12GE. The above materials can be used for the gate electrode 32GE in a single layer or in a multilayer.

Next, as shown in FIG. 4 and FIG. 10, impurity elements are added to the oxide semiconductor layer 24 using the gate electrode 32GE as a mask (step S1014 “impurity addition (SD region formation)” shown in FIG. 4). In this embodiment, the addition of impurity elements is performed by an ion implantation, but it may also be performed by the ion doping method.

Specifically, by means of the ion implantation, impurity elements are added to the second region 24b of the oxide semiconductor layer 24, passing through the gate insulating layer 26. For example, argon (Ar), phosphorus (P), or boron (B) can be used as the impurity element. When adding boron (B) using the ion implantation method, the acceleration energy should be set to 20 keV or more and 40 keV or less, and the amount of boron (B) implanted should be set to 1×10¹⁴ cm⁻² or more and 1×10¹⁶ cm⁻² or less.

Impurity elements can be added to the second region 24b at a concentration of 1×10¹⁸ cm⁻³ or more and 1×10²¹ cm⁻³ or less. At this time, the oxide semiconductor in the second region 24b forms oxygen deficiencies due to the addition of impurity elements. Electrons are easily trapped in these oxygen deficiencies. This reduces the resistance of the second region 24b, allowing it to function as a conductor.

The first region 24a and the third region 24c of the oxide semiconductor layer 24 do not have impurity elements added because they overlap the gate electrode 32GE. In addition, the first region 24a is supplied with oxygen from both the oxide insulating layer 14b and the gate insulating layer 26 through oxygen annealing. This increases the resistance of the first region 24a, allowing it to function as a semiconductor. In the third region 24c, oxygen is supplied from the gate insulating layer 26 by oxidation annealing, but the oxygen from the oxide insulating layer 14b is blocked by the metal oxide layers 18-1 and 18-2. As a result, the resistance in the third region 24c can be made lower than that in the first region 24a and higher than that in the third region 24c. Therefore, the third region 24c can be made to function like an LDD region.

For example, when using IZO as the oxide semiconductor layer 24, the resistance of the oxide semiconductor is high, so the thickness of the film must be increased in order to sufficiently reduce the resistance of the source and drain regions. In contrast, in the oxide semiconductor layer 24, which has a polycrystalline structure, the sheet resistance can be reduced even if the film thickness is small by adding impurity elements to the second region 24b. In this embodiment, the sheet resistance of the second region 24b can be 1000 Ω/sq. or less, preferably 500 Ω/sq. or less, and even more preferably 250 Ω/sq. or less.

As shown in FIG. 4, an interlayer insulating film 34 is formed as an interlayer film on the gate insulating film 26 and the gate electrode 32GE (step S1015 “interlayer film formation” shown in FIG. 4).

The method of forming the interlayer insulating film 34 and the insulating material can be found in the description of the gate insulating film 14. A thickness of the interlayer insulating film 34 is 50 nm or more and 500 nm or less. In this embodiment, the interlayer insulating film 34 is formed by laminating silicon oxide and silicon nitride.

Next, contact holes CH2 and CH3 are formed in the gate insulating layer 26 and the interlayer insulating layer 34 (step S1016 “contact hole formation” shown in FIG. 4). The second region 24b of the oxide semiconductor layer 24 is exposed by the contact holes CH2 and CH3.

Finally, by forming the source electrode 36SE and the drain electrode 36DE on the oxide semiconductor layer 24 and the interlayer insulating layer 34, which have been exposed by the contact hole (step S1017 “SD formation” shown in FIG. 4), the semiconductor device 10 shown in FIG. 1 can be formed.

The source electrode 36SE and the drain electrode 36DE are formed by processing a conductive film deposited by a sputtering method, for example. The source electrode 36SE and the drain electrode 36DE are made of the same general metal materials as the gate electrode 12GE. For information on the materials that can be used for the source electrode 36SE and the drain electrode 36DE, please refer to the description of the gate electrode 12GE. The above materials can be used for the source electrode 36SE and the drain electrode 36DE either as a single layer or as a multilayer.

The above process can be used to manufacture the semiconductor device 10 shown in FIG. 1.

### First Modification

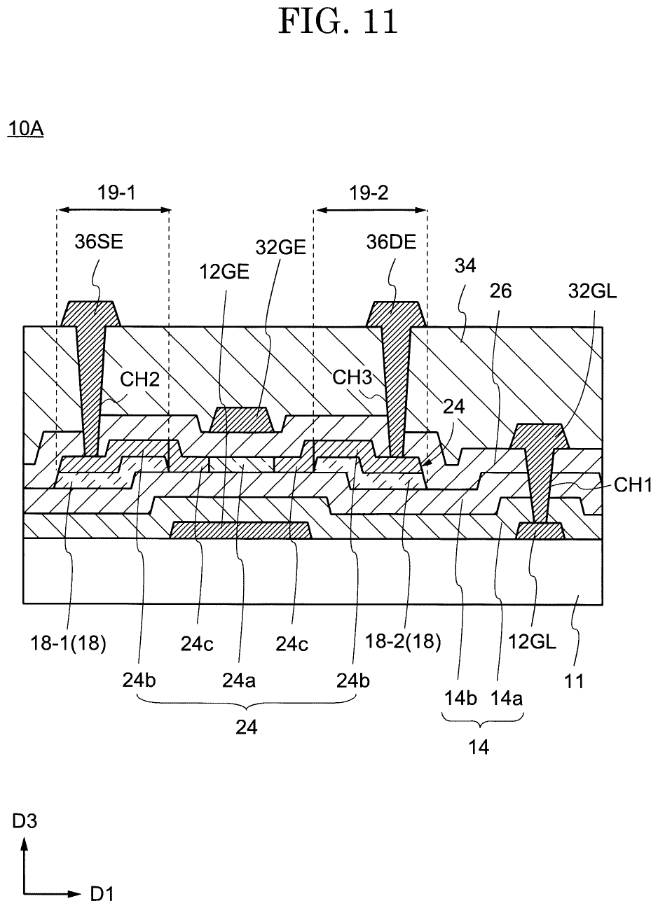

Next, FIG. 11 to FIG. 22 explain the semiconductor devices 10A to 10E, which have a partially different structure from semiconductor device 10. Unless otherwise specified, the semiconductor devices 10A to 10E explain the case where Poly-OS is used as the oxide semiconductor layer 24 and aluminum oxide is used as the metal oxide film 17 and the metal oxide layer 18.

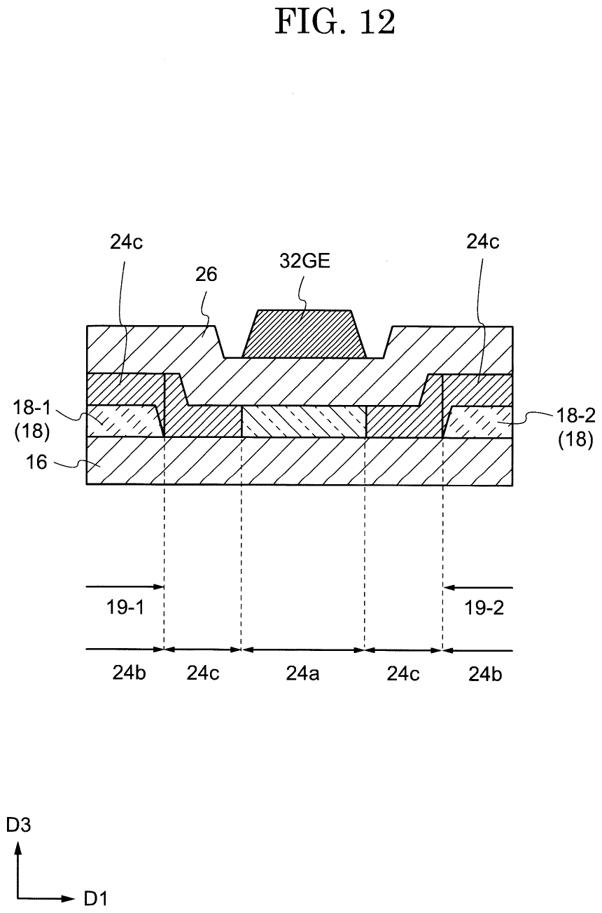

FIG. 11 shows the semiconductor device 10A according to an embodiment of the present invention. FIG. 12 is an enlarged view of a portion of the semiconductor device 10A shown in FIG. 11. The semiconductor device 10A shown in FIG. 11 has a structure in which the gate electrode 32GE does not overlap the first region 19-1 and the second region 19-2. In other words, the gate electrode 32GE is provided between the metal oxide layer 18-1 and the metal oxide layer 18-2, which are separated from each other. The manufacturing method for the semiconductor device 10A shown in FIG. 11 is the same as that of the semiconductor device 10, so it will be explained by referring to the semiconductor device 10 as appropriate.

In FIG. 11, the width of the gate electrode 12GE in the direction D1 is longer than the length of the metal oxide layer 18-1 and the metal oxide layer 18-2, and the width of the gate electrode 32GE is shorter than the length of the metal oxide layer 18-1 and the metal oxide layer 18-2.

When manufacturing a semiconductor device 10A, during step S1011 as shown in FIG. 4, the oxide semiconductor layer 24 in contact with the oxide insulating film 14b is supplied with oxygen from both the oxide insulating film 14b and the gate insulating film 26, thereby reducing oxygen deficiencies. In addition, the oxide semiconductor layer 24, which is in contact with the metal oxide layers 18-1 and 18-2, is supplied with oxygen from the gate insulating layer 26, but the supply of oxygen from the oxide insulating layer 14b is suppressed, so the repair of oxygen deficiencies is suppressed. After going through steps S1012 and S1013 as shown in FIG. 4, impurity elements are added to the oxide semiconductor layer 24 using the gate electrode 32GE as a mask during step S1014.

A region of the oxide semiconductor layer 24 that overlaps the gate electrode 32GE is not doped with impurity elements because it overlaps the gate electrode 32GE. This region has had its oxygen deficiencies repaired by oxidation annealing, and no impurity elements have been added to it since then. This region can function as a semiconductor and can function as a channel region (the first region 24a). In the oxide semiconductor layer 24, the region that does not overlap with the gate electrode 32GE and overlaps both the metal oxide layers 18-1 and 18-2 has had the repair of oxygen suppressed by oxidation annealing and has also had impurity elements added. This region can be made to function as a conductor and can be made to function as a source region and a drain region (the second region 24b). In the oxide semiconductor layer 24, the region that does not overlap the gate electrode 32GE and the metal oxide layer 18-1, 18-2 has had its oxygen deficiencies repaired by oxidation annealing and has had impurity elements added. Therefore, the resistance of this region can be made higher than that of the second region 24b and lower than that of the first region 24a. This allows the region to function in the same way as an LDD region. The region that is made to function as an LDD region is called the third region 24c.

### Second Modification

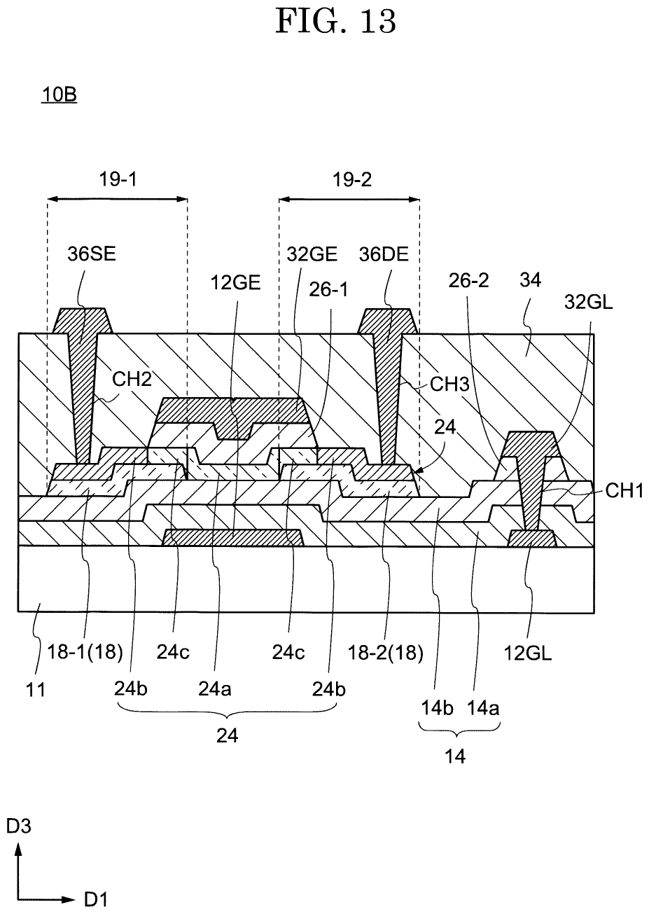

FIG. 13 shows the semiconductor device 10B according to an embodiment of the present invention. In the semiconductor device 10B, the gate insulating film 26 is removed below the gate electrode 32GE and below the gate wiring 32GL. In other words, the second region 24b of the oxide semiconductor layer 24 is exposed. The method for manufacturing the semiconductor device 10B shown in FIG. 13 is the same as that for the semiconductor device 10, so it will be explained by referring to it as appropriate.

When manufacturing the semiconductor device 10B, after the gate electrode 32GE and the gate wiring 32GL are etched and formed in step S1013 as shown in FIG. 4, the gate insulating film 26 can be removed by further etching. The oxide semiconductor layer 24, which has a crystalline structure, has the property of being difficult to etch, so it is possible to suppress its disappearance by etching. In addition, etching causes oxygen deficiencies to form on the surface of the oxide semiconductor layer 24 that has been exposed. During step S1015 shown in FIG. 4, electrons originating from the hydrogen contained in the interlayer insulating layer 34 are easily trapped in the oxygen deficiencies. Therefore, it is possible to reduce the resistance of the second region 24b.

### Third Modification

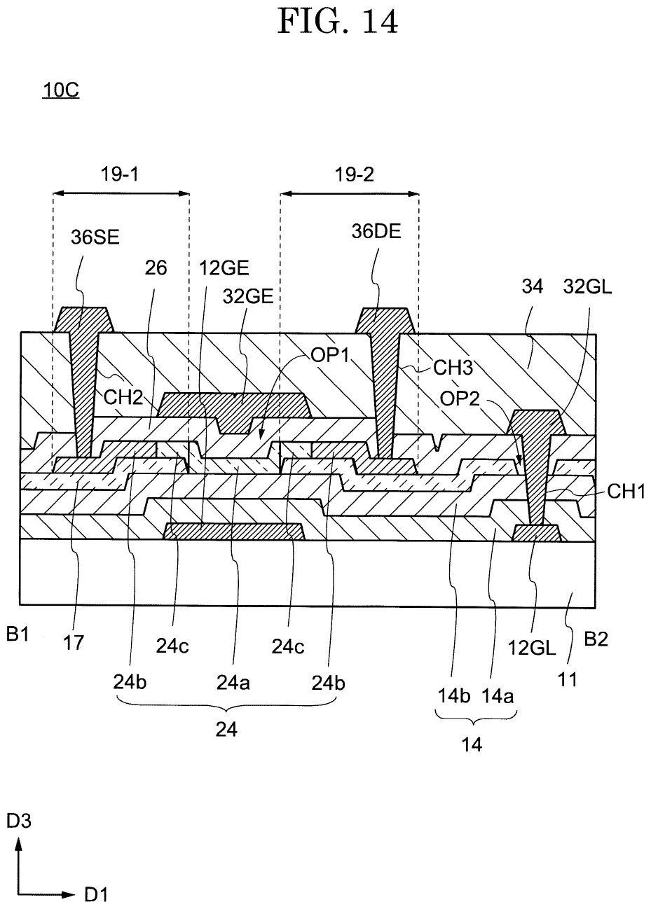

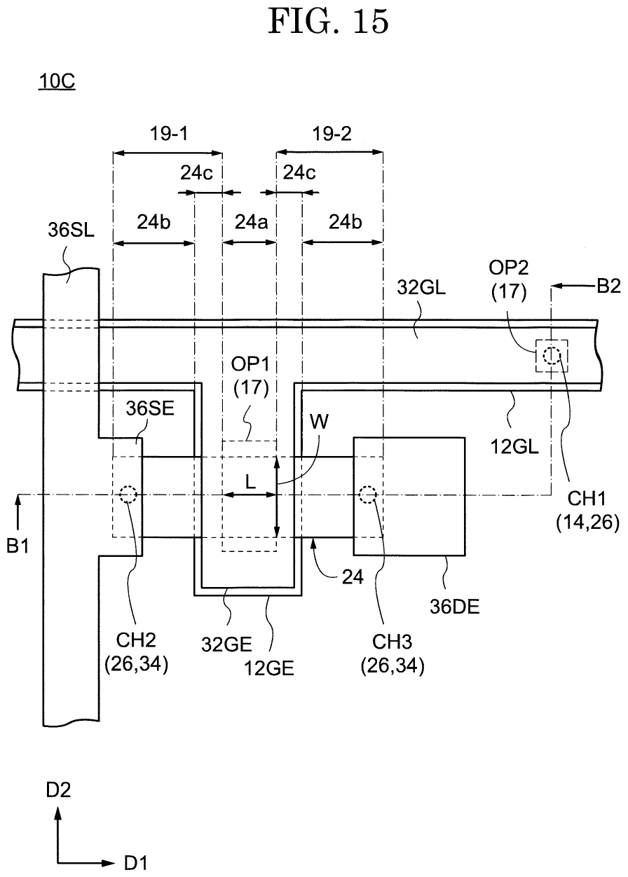

FIG. 14 shows the semiconductor device 10C according to an embodiment of the present invention. FIG. 15 shows a plan view of the semiconductor device 10C according to an embodiment of the present invention. The semiconductor device 10C has the opening OP1 in the metal oxide film 17. The metal oxide film 17 has the opening OP1 between the first region 19-1 and the second region 19-2. In addition, the opening OP2 is provided in a region where the gate wiring 12GL and the gate wiring 32GL are connected to the metal oxide film 17. In the metal oxide film 17, a region that is in contact with the second region 24b of the oxide semiconductor layer 24 corresponds to the first region 19-1 and the second region 19-2. The method for manufacturing the semiconductor device 10C shown in FIG. 14 is the same as the method for manufacturing the semiconductor device 10, so it will be explained by referring to it as appropriate.

When manufacturing the semiconductor device 10C, in step S1004 as shown in FIG. 4, not only is the opening OP1 formed in the region that overlaps the gate electrode 12GE, but also the opening OP2 is formed in the region that overlaps the gate wiring 12GL. The openings OP1 and OP2 can be formed, for example, by wet etching using hydrofluoric acid. In the semiconductor device 10C, the metal oxide film 17 is formed in a film-like manner over the entire surface of the substrate 11. Therefore, the process of patterning the metal oxide film 17 in step S1008 shown in FIG. 4 is omitted. Since the metal oxide film 17 is not easily etched, it is difficult to form contact holes using the same process as the nitride insulating film 14a, the oxide insulating film 14b, and the gate insulating film 26. Therefore, by forming the opening OP2 in advance during step S1004 as shown in FIG. 4, it becomes easier to form the contact holes CH1 in the nitride insulating film 14a, the oxide insulating film 14b, and the gate insulating film 26 in the subsequent process.

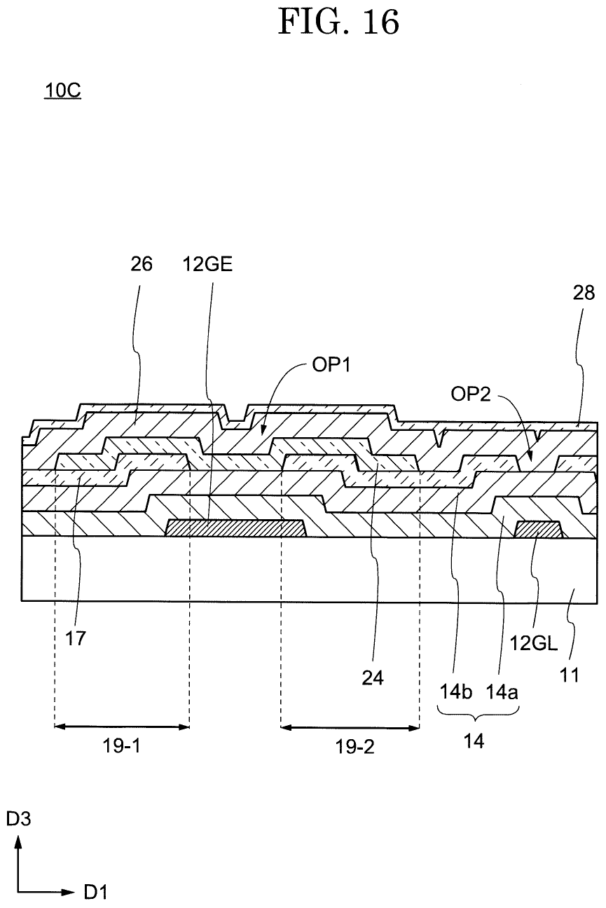

When manufacturing the semiconductor device 10C, oxidation annealing is performed with the metal oxide film 17 and the gate insulating film 26 in contact with each other in step S1011 as shown in FIG. 4. FIG. 16 is a diagram explaining the oxidation annealing process when manufacturing the semiconductor device 10C. As a result, the oxygen emitted from the oxide insulating film 14b is blocked by the metal oxide film 17, but is supplied to the region of the oxide semiconductor layer 24 that is in contact with the oxide insulating film 14b. In FIG. 16, the metal oxide film 17 is provided in the form of a film over the entire surface of the substrate 11, so there is almost no contact between the oxide insulating film 14b and the gate insulating film 26. Therefore, during the oxidation annealing process, the transfer of oxygen released from the oxide insulating film 14b to the gate insulating film 26 can be suppressed. This in turn suppresses the supply of oxygen to the second region 24b of the oxide semiconductor layer 24. In addition, because oxygen is supplied intensively to the first region 24a of the oxide semiconductor layer 24, the oxygen deficiency in the first region 24a can be repaired.

### Forth Modification

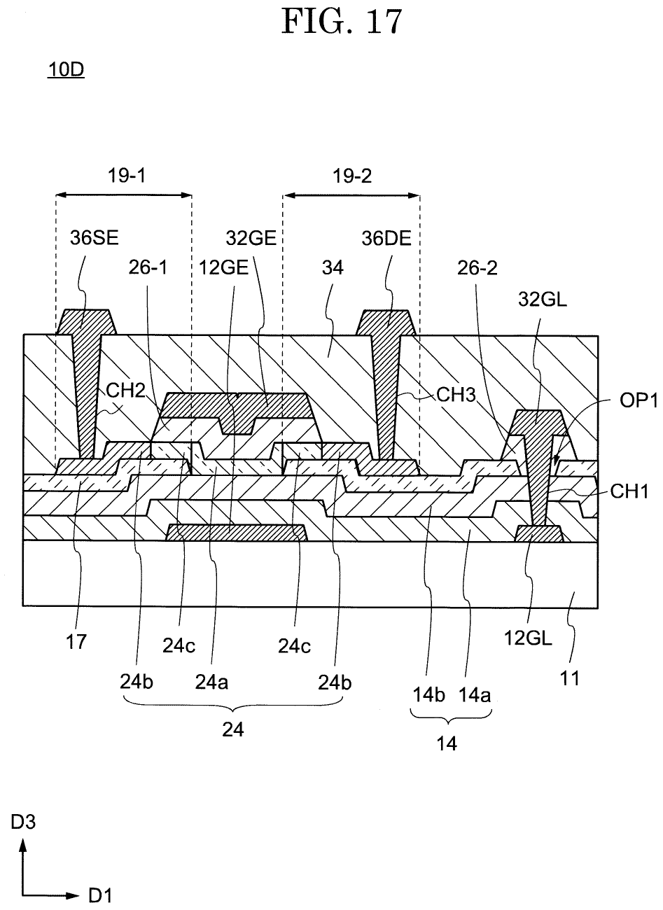

FIG. 17 shows the semiconductor device 10D according to an embodiment of the present invention. In the structure of the semiconductor device 10D, the gate insulating layer 26 is removed below the gate electrode 32GE and below the gate wiring 32GL. In other words, the second region 24b of the oxide semiconductor layer 24 is exposed. The manufacturing method for the semiconductor device 10D shown in FIG. 17 is the same as the manufacturing method for the semiconductor device 10C, so it will be explained by referring to the semiconductor device 10C as appropriate.

When manufacturing the semiconductor device 10D, after the gate electrode 32GE and the gate wiring 32GL are etched and formed in step S1013 as shown in FIG. 4, the gate insulating film 26 can be removed by further etching. The oxide semiconductor layer 24, which has a crystalline structure, has the property of being difficult to etch, so it is possible to suppress its disappearance by etching. In addition, etching causes oxygen deficiencies to form on the surface of the oxide semiconductor layer 24. During step S1015 shown in FIG. 4, electrons originating from the hydrogen contained in the interlayer insulating layer 34 are easily trapped in these oxygen deficiencies. Therefore, it is possible to reduce the resistance of the second region 24b.

### Fifth Modification

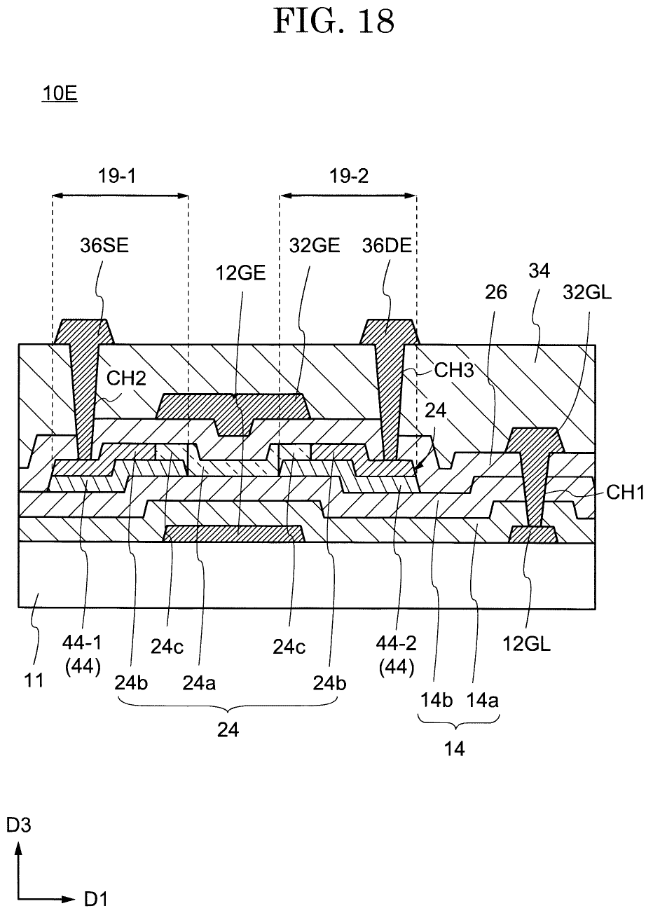

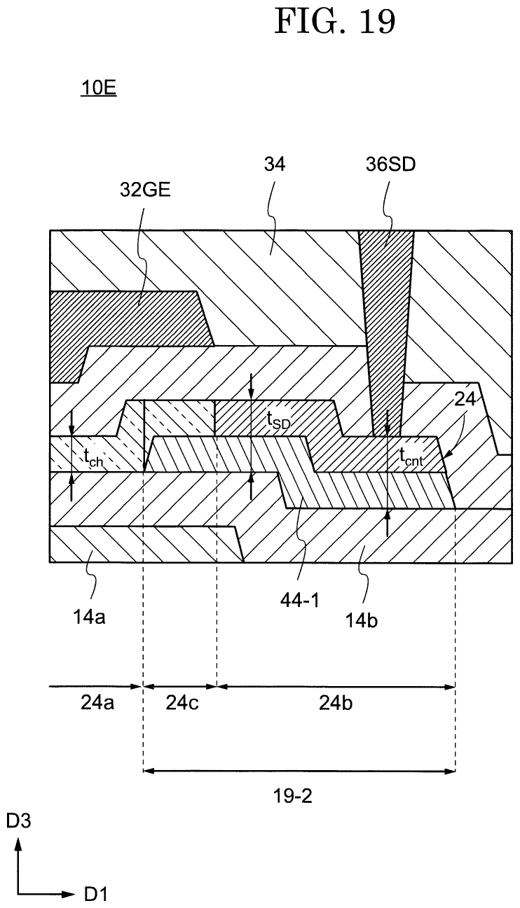

FIG. 18 shows the semiconductor device 10E according to an embodiment of the present invention. FIG. 19 is an enlarged view of part of the semiconductor device 10E shown in FIG. 11. In the semiconductor device 10E shown in FIG. 18, oxide semiconductors are used as the metal oxide layers 18-1 and 18-2 instead of aluminum oxide. In the semiconductor device 10E, oxide semiconductor layers 44-1 and 44-2 are referred to as such in order to distinguish them from the metal oxide layers 18-1 and 18-2, which use aluminum oxide. The oxide semiconductor layers 44-1 and 44-2 are sometimes referred to as an oxide semiconductor layer 44.

The oxide semiconductor layers 44-1 and 44-2 have the function of inhibiting the permeation of oxygen and hydrogen emitted from the adjacent insulating layer. As the oxide semiconductor layers 44-1 and 44-2, metal oxides having semiconductor characteristics can be used. As the oxide semiconductor layers 44-1 and 44-2, for example, an oxide semiconductor containing two or more metal elements including indium (In) is used. In addition to indium, gallium (Ga), zinc (Zn), aluminum (Al), hafnium (Hf), yttrium (Y), zirconium (Zr), or lanthanide elements are used as the oxide semiconductor layers 44-1 and 44-2. Elements other than those listed above may be used as the oxide semiconductor layers 44-1 and 44-2. In this variant, Indium Gallium Zinc Oxide (IGZO) is used as the oxide semiconductor layers 44-1 and 44-2, and Poly-OS is used as the oxide semiconductor layer 24. In this case, an amount of indium contained in the oxide semiconductor layer 24 is greater than an amount of indium contained in the oxide semiconductor layers 44-1 and 44-2. As shown here, in the semiconductor device 10E, the oxide semiconductor material may differ between the oxide semiconductor layer 24 and the oxide semiconductor layers 44-1 and 44-2.

A thickness of the oxide semiconductor layers 44-1 and 44-2 is, for example, larger than 5 nm and 50 nm or less, larger than 5 nm and 30 nm or less, larger than 5 nm and 20 nm or less, or larger than 5 nm and 10 nm or less. If a thickness of the oxide semiconductor layers 44-1 and 44-2 is at least larger than 5 nm, the permeation of oxygen and hydrogen from the adjacent insulating membrane can be suppressed. The oxide semiconductor layer 44 has the first region 19-1 and the second region 19-2 that are separated from each other. In other words, the first region 19-1 and the second region 19-2 are regions of the oxide semiconductor layer 44 that are in contact with the oxide semiconductor layer 24. In FIG. 18, the oxide semiconductor layer 44 includes the oxide semiconductor layer 44-1, which includes the first region 19-1, and the metal oxide layer 18-2, which includes the second region 19-2.

The oxide semiconductor layers 44-1 and 44-2 block the oxygen released from the oxide insulating layer 14b, and also function as semiconductor layers in the semiconductor device 10E. Therefore, the oxide semiconductor layer 24 and the oxide semiconductor layers 44-1 and 44-2 can be considered as a single semiconductor layer. In this case, a thickness t_{ch} of the first region 24a (channel region) is a thickness of the oxide semiconductor layer 24 alone. A thickness t_{SD} of the second region 24b (source and drain regions) is a thickness of the oxide semiconductor layer 24 and the oxide semiconductor layer 44-1 or the oxide semiconductor layer 44-2. The thickness t_{CNT} of a region in the second region 24b where the contact hole CH3 is formed is a thickness of the oxide semiconductor layer 24 and the oxide semiconductor layer 44-1 or the oxide semiconductor layer 44-2. When the contact hole CH3 is formed, the second region 24b may be thinned. Therefore, it is sufficient if a thickness of the oxide semiconductor layers 24 and 44 satisfies the relationship t_{ch}<t_{cnt}≤t_{SD}. The thinner the oxide semiconductor layer 24, the less oxygen is supplied to oxidize the oxide semiconductor layer 24. Therefore, the thinner the oxide semiconductor layer 24, the lower the resistance can be achieved with less oxygen supply. Therefore, by satisfying the relationship t_{ch}<t_{cnt}≤tₛₚ for the thicknesses of the oxide semiconductor layers 24 and 44, it is possible to make the channel region low-resistance, and it is also easier to make the source and drain regions low-resistance.

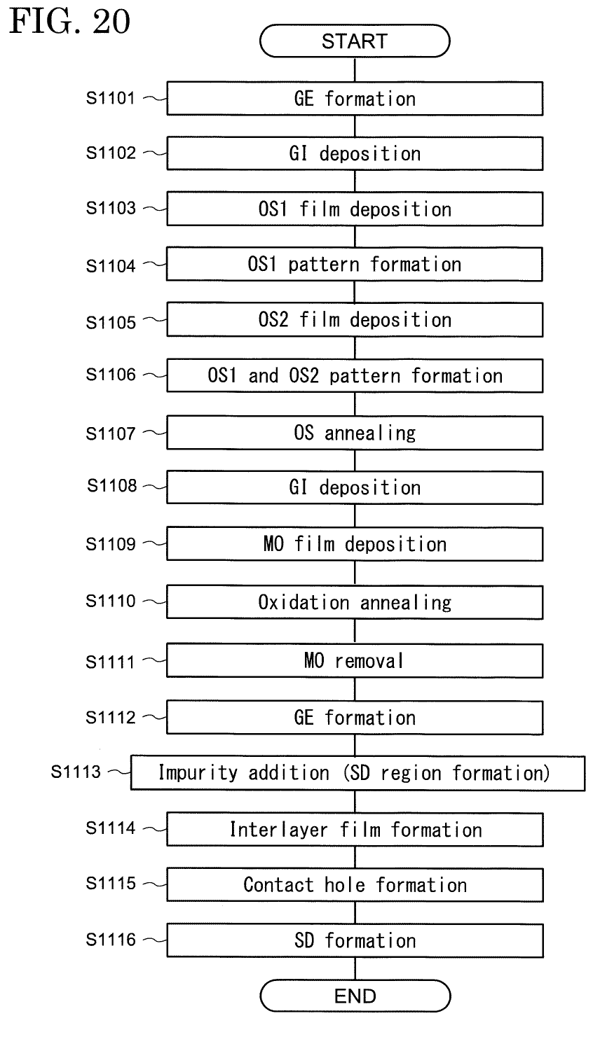

FIG. 20 is a sequence diagram showing the manufacturing method for the semiconductor device 10E according to an embodiment of the present invention. The manufacturing method for the semiconductor device 10E shown in FIG. 20 includes many of the same processes as the semiconductor device 10 and thus only the differences will be explained.

As shown in FIG. 20, an oxide semiconductor film 43 made of IGZO is formed on the oxide insulating film 14b (step S1103 “OS1 film deposition” shown in FIG. 20). The oxide semiconductor layer 43 is formed by sputtering or atomic layer deposition (ALD). A thickness of the oxide semiconductor layer 43 is, for example, larger than 5 nm and 50 nm or less, larger than 5 nm and 30 nm or less, larger than 5 nm and 20 nm or less, or larger than 5 nm and 10 nm or less.

As shown in FIG. 20, the opening OP1 is formed in the oxide semiconductor film 43 (step S1104 “OS1 pattern formation” shown in FIG. 4). The opening OP1 in the oxide semiconductor film 43 is formed in a region that overlaps the gate electrode 12GE. Although not shown in the figure, the opening OP1 is formed so that it is parallel to the direction in which the gate electrode 12GE extends. The width of the opening OP1 corresponds to the channel length L of the channel region that will be formed later.

As shown in FIG. 20, the oxide semiconductor film 21 is formed on the oxide semiconductor film 43 (step S1105 “OS2 film deposition” shown in FIG. 20). Here, the content of indium in the oxide semiconductor film 21 is greater than the content of indium in the oxide semiconductor film 43.

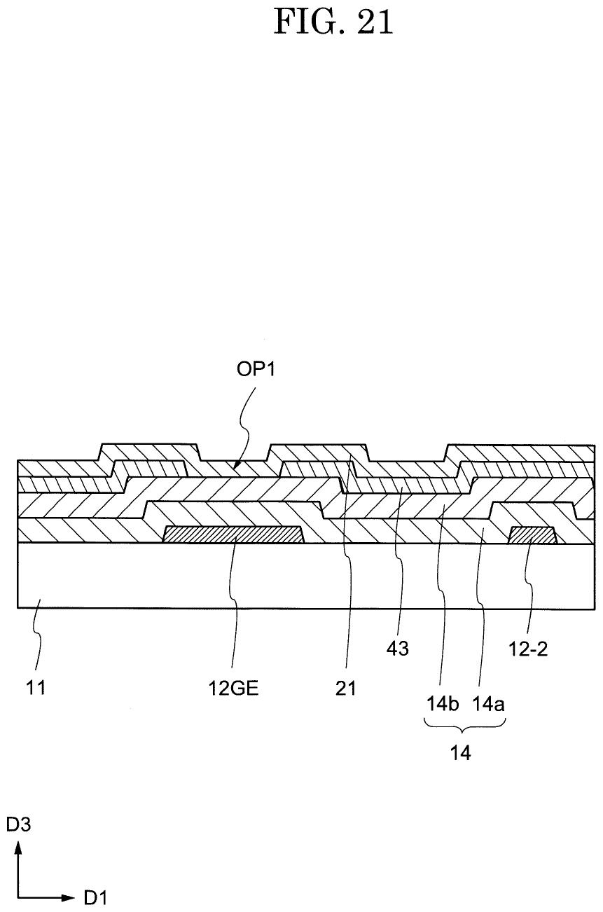

As shown in FIG. 20 and FIG. 21, the patterns of the oxide semiconductor layer 44 and the oxide semiconductor layer 24 are formed (step S1106 “OS1 and OS2 pattern formation” shown in FIG. 20). A resist mask is formed on the oxide semiconductor layer 21, and the oxide semiconductor layers 43 and 21 are etched using the resist mask 23. This allows the patterned oxide semiconductor layers 22 and 44 to be formed. The resist mask 23 is then removed. The processes in steps S1107 to S1116 shown in FIG. 20 are the same as the processes in steps S1007, S1009 to S1017 shown in FIG. 4.

In the semiconductor device 10E, as in the case where aluminum oxide is used in the metal oxide layers 18-1 and 18-2, the oxide semiconductor layers 44-1 and 44-2 have the effect of blocking the oxygen emitted from the oxide insulating layer 14b. Therefore, the semiconductor device 10E can obtain good reliability test results and increase the on-current.

Although not explained in detail, in semiconductor devices 10A and 10B, IGZO may also be used as the metal oxide layer 18 instead of aluminum oxide. If IGZO is used as the metal oxide layer 18, it is sufficient to refer to the description of the oxide semiconductor layer 44 of the semiconductor device 10E. In this case, the content of indium in the oxide semiconductor layer 24 is greater than the content of indium in the metal oxide layer 18. In the semiconductor device 10F, the oxide semiconductor materials used in the oxide semiconductor layer 24 and the metal oxide layer 18 may differ.

### Second Embodiment

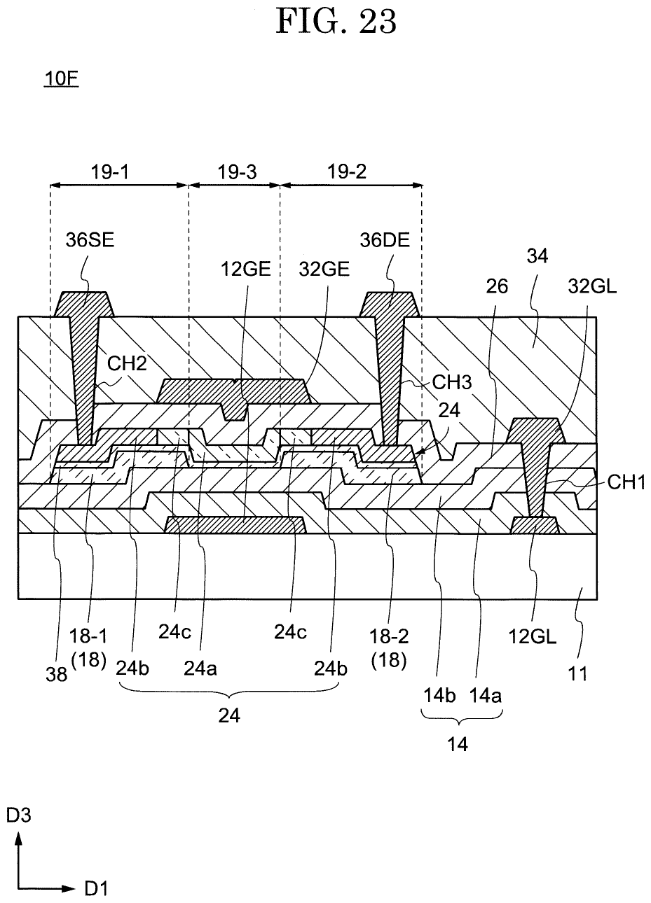

FIG. 23 to FIG. 31 are used to explain semiconductor devices 10F to 10H according to an embodiment of the present invention. Unless otherwise specified, in the semiconductor devices 10F to 10H, Poly-OS is used as the oxide semiconductor layer 24, and aluminum oxide is used as the metal oxide films 17 and 37 and the metal oxide layers 18 and 38.

### Configuration of Semiconductor device 10F

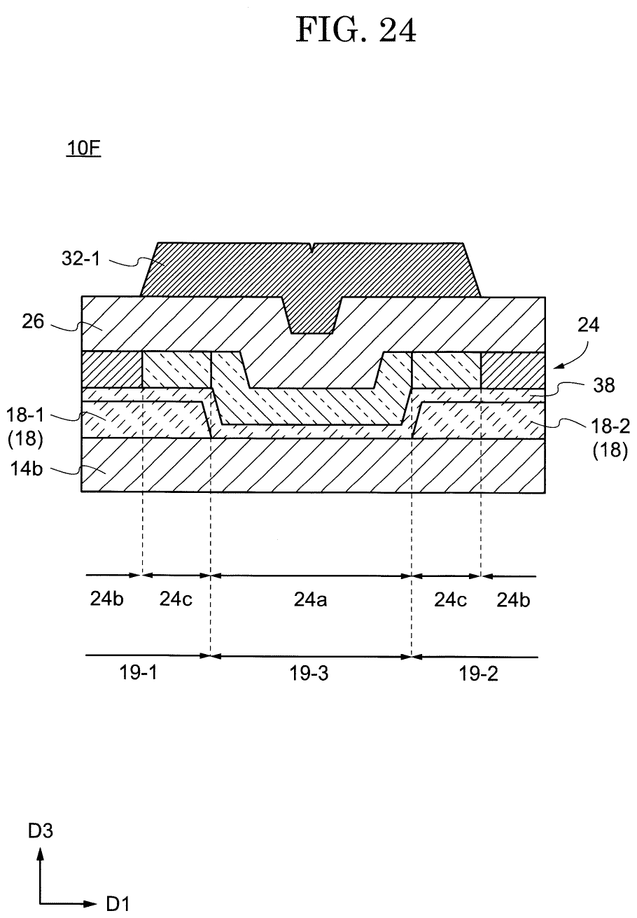

FIG. 23 to FIG. 26 are used to explain the configuration of the semiconductor device 10F according to an embodiment of the present invention. FIG. 23 is a cross-sectional view showing an overview of semiconductor device 10F according to an embodiment of the present invention. FIG. 24 is an enlarged view of part of semiconductor device 10F shown in FIG. 1.

As shown in FIG. 23, the semiconductor device 10F is provided on the upper side of the substrate 11. The semiconductor device 10F includes at least the oxide insulating film 14b, the metal oxide layer 38, the metal oxide layers 18-1 and 18-2, the oxide semiconductor layer 24, the gate insulating film 26, and the gate electrode 32GE. The oxide semiconductor layer 24, the gate insulating film 26, and the gate electrode 32GE are sometimes referred to as a transistor. The semiconductor device 10F may further include a gate electrode 12GE, the nitride insulating film 14a, the interlayer insulating film 34, the source electrode 36SE, and the drain electrode 36DE. The configuration of the semiconductor device 10F is the same as that of the semiconductor device 10, except that a metal oxide layer 38 is provided between the metal oxide layers 18-1 and 18-2 and the oxide semiconductor layer 24.

The metal oxide layers 18 and 38 are layers that include metal oxide layers with aluminum as the main component, and they have the function of acting as a gas barrier film that blocks gases such as oxygen and hydrogen. The metal oxide layers 18 and 38 have the first region 19-1 and the second region 19-2 that are provided at a distance from each other, and a third region 19-3 that is provided between the first region 19-1 and the second region 19-2. Specifically, it includes 38 metal oxide layers, which have a portion 1_1 (a first-first portion) corresponding to the first region, a portion 1_2 (a first-second portion) corresponding to the second region, and a portion 1_3 (a first-third portion) corresponding to the third region, and the metal oxide layer 18-1 corresponding to the first region, which is located under the portion 1_1, and the metal oxide layer 18-2 corresponding to the second region, which is located under the portion 1_2.

The metal oxide layers 18 and 38 have the function of inhibiting the permeation of oxygen supplied from the adjacent oxide insulating layer 14b. For this reason, the metal oxide layers 18 and 38 can be considered as a single metal oxide layer.

The metal oxide layer 38 is formed on the oxide insulating layer 14b and the metal oxide layers 18-1 and 18-2. The metal oxide layer 38 is aluminum oxide. The thickness of the metal oxide layers 18-1 and 18-2 is larger than the thickness of the metal oxide layer 38. The thickness of the metal oxide layer 38 is 5 nm or less. The metal oxide layers 18-1 and 18-2 are aluminum oxide. The thickness of the metal oxide layer 18-1 and the thickness of the metal oxide layer 18-2 are, for example, larger than 5 nm and 50 nm or less, larger than 5 nm and 30 nm or less, larger than 5 nm and 20 nm or less, or larger than 5 nm and 10 nm or less. If the metal oxide layers 18 and 38 are considered to be a single metal oxide layer, it is sufficient if the thickness of the metal oxide layer in the first region 19-1 and the second region 19-2 is larger than the thickness of the metal oxide layer in the third region 19-3. In addition, when the metal oxide layers 18 and 38 are considered to be a single metal oxide layer, the total thickness of the metal oxide layers 18 and 38 in regions 19-1 and 19-2 may be larger than 5 nm and 50 nm or less.

### Method for Manufacturing Semiconductor Device 10F

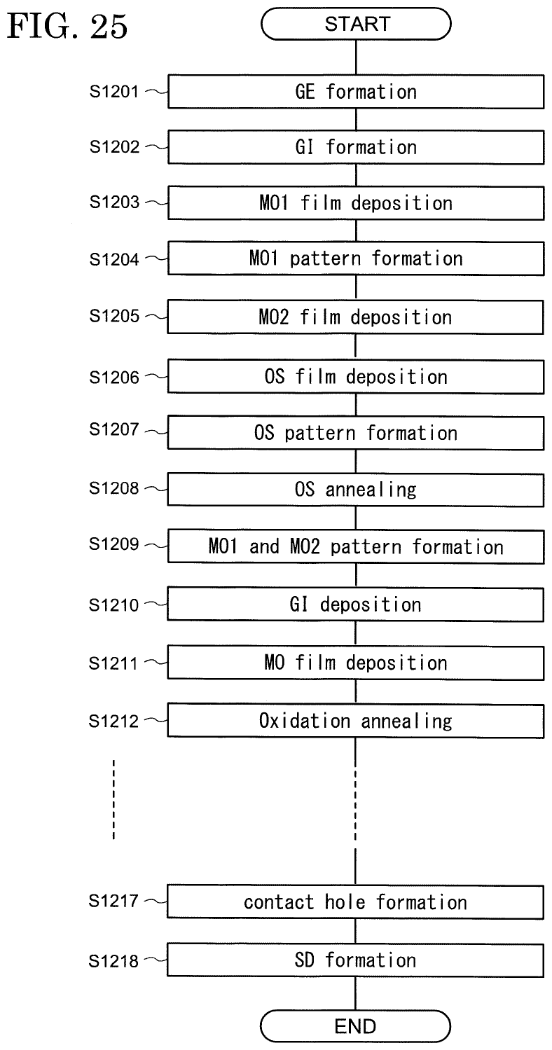

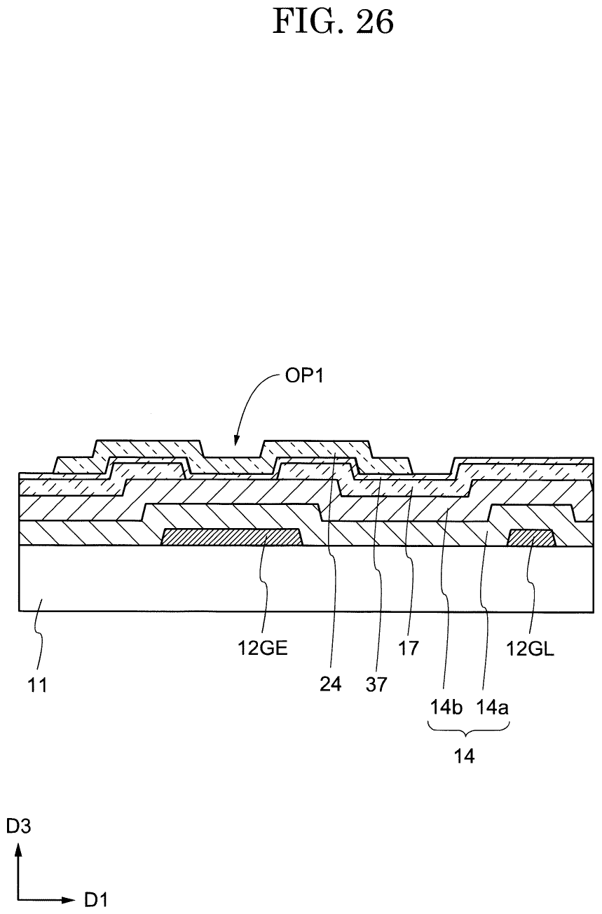

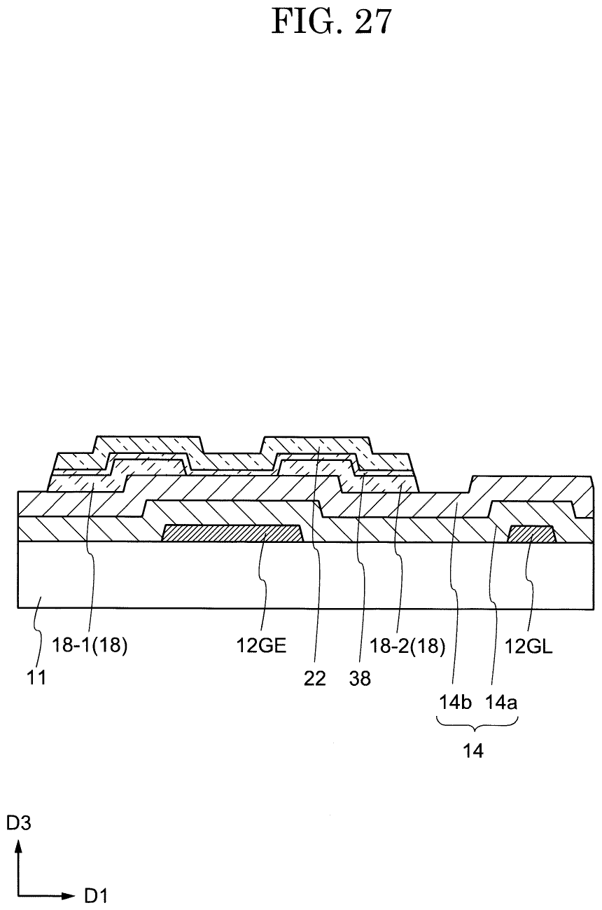

FIG. 25 to FIG. 27 are for explaining the method for manufacturing the semiconductor device 10F according to an embodiment of the present invention. FIG. 25 is a sequence diagram showing the method for manufacturing the semiconductor device 10F according to an embodiment of the present invention. In FIG. 25, the processes from Step S1213 to Step S1216 are omitted, but they are the same as the processes from Step S1012 to Step S1015 shown in FIG. 4, so it is sufficient to refer to them as appropriate. FIG. 26 and FIG. 27 are a cross-sectional view showing a method for manufacturing the semiconductor device 10F according to an embodiment of the present invention.

The processes shown in steps S1201 to S1204 in FIG. 25 are the same as the processes shown in steps S1001 to S1004 in FIG. 3. The process in step S1204 forms the opening OP1 in the metal oxide film 17.

As shown in FIG. 25, a metal oxide film 37 is formed on the metal oxide film 17 (step S1205 “MO2 film formation” shown in FIG. 25). The metal oxide film 37 is made of a metal oxide that is mainly composed of aluminum, as is the case with the metal oxide film 17. The metal oxide film 37 can be formed using the same method as the metal oxide film 17. The thickness of the metal oxide film 37 is preferably 5 nm or less.

The processes shown in steps S1206 to S1208 in FIG. 25 are the same as the processes shown in steps S1005 to S1007 in FIG. 4. The process in step S1208 forms the oxide semiconductor layer 24 with a polycrystalline structure, as shown in FIG. 26.

As shown in Step S1209 “MO1, MO2 patterning” in FIG. 25, the metal oxide films 17 and 37 are patterned using the oxide semiconductor layer 24 as a mask. This allows the formation of the metal oxide layer 38, the metal oxide layer 18-1, and the metal oxide layer 18-2, as shown in FIG. 27. As shown in FIG. 27, the sidewalls of the metal oxide layer 18-1, the sidewalls of the metal oxide layer 18-2, the sidewalls of the metal oxide layer 38, and the sidewalls of the oxide semiconductor layer 24 are aligned in a straight line.

The process from Step S1210 to Step S1212 shown in FIG. 25 is the same as the process from Step S1009 to Step S1011 shown in FIG. 4. The oxygen released from the gate insulating film 26 and the oxide insulating film 14b is blocked by the metal oxide film 28 through the oxidation annealing shown in Step S1212. As a result, the top surface and side surface of the oxide semiconductor layer 24 are supplied with oxygen released from the gate insulating film 26 and the oxide insulating film 14b.

As mentioned above, oxygen deficiencies in the oxide semiconductor layer 24 are not distributed uniformly in the thickness direction of the oxide semiconductor layer 22, but rather there are more oxygen deficiencies on the top surface of the oxide semiconductor layer 24 than on the bottom surface. When the bottom surface of the oxide semiconductor layer 24 is in contact with the oxide insulating layer 14b, there is a possibility that excess oxygen will be supplied to the bottom surface of the oxide semiconductor layer 24. As a result, the underside of the layer may form defect levels that are different from oxygen deficiencies due to the excess oxygen, causing phenomena such as characteristic fluctuations in reliability tests or a decrease in field effect mobility. Therefore, in order to suppress such phenomena, it is necessary to supply oxygen to the upper side of the oxide semiconductor layer 22 while suppressing the supply of oxygen to the underside of the oxide semiconductor layer 22.

In the semiconductor device 10F, the metal oxide layer 38 of 5 nm or less is provided between the oxide semiconductor layer 24 and the oxide insulating layer 14b. Because the metal oxide layer 38 is thin, it can both transmit and block oxygen from the oxide insulating layer 14b.

In the first region 24a, oxygen is supplied from both the oxide insulating film 14b and the gate insulating film 26 through a thermal treatment. The metal oxide layer 38 is provided in the first region 24a, but because the film thickness is thin, at 5 nm or less, oxygen from the oxide insulating film 14b can permeate through it. Therefore, compared to the semiconductor device 10, the excessive supply of oxygen to the first region 24a can be suppressed, and the generation of defect levels can be suppressed. The resistance of the first region 24a can be increased by oxidation annealing, so it can function as a semiconductor. Therefore, the first region 24a functions as a channel region. The resistance of the first region 24a is higher than that of the second region 24b and the third region 24c.

The second region 24b and the third region 34c overlap the metal oxide layers 18-1 and 18-2, and the metal oxide layer 38. In the second region 24b, oxygen is supplied from the gate insulating layer 26 by a thermal treatment, but the transfer of oxygen from the oxide insulating layer 14b is suppressed by the metal oxide layers 18-1, 18-2, and 38. As a result, the resistance of the second region 24b and the third region 24c can be reduced compared to the first region 24a. In addition, the resistance of the second region 24b can be reduced compared to the third region 24c by adding impurity elements after oxidation annealing. The second region 24b can function as a source region and a drain region, and the third region 24c can function as an LDD region.

By forming the metal oxide layer 38 of 5 nm or less in a thickness in the third region 19-3, it is possible to suppress the excessive supply of oxygen from the oxide insulating layer 14b to the oxide semiconductor layer 24. As a result, it is possible to suppress the formation of defect levels due to excessive oxygen deficiency on the underside, thereby suppressing characteristic fluctuations in reliability tests and increasing the field effect mobility.

The processes from Step S1213 to Step S1218 in FIG. 25 are the same as the processes from Step S1011 to Step S1017 in FIG. 4. The above processes can be used to manufacture the semiconductor device 10F shown in FIG. 23.

In the semiconductor device 10F, IGZO may be used in place of aluminum oxide as the metal oxide layer 18. If IGZO is used as the metal oxide layer 18, it is sufficient to refer to the description of the oxide semiconductor layer 44 in the semiconductor device 10E. If IGZO is used as the metal oxide layer 18, it is preferable to use aluminum oxide as the metal oxide layer 38. In this case, the amount of indium contained in the oxide semiconductor layer 24 is greater than the amount of indium contained in the metal oxide layer 18. In the semiconductor device 10F, the oxide semiconductor materials used in the oxide semiconductor layer 24 and the metal oxide layer 18 may be different.

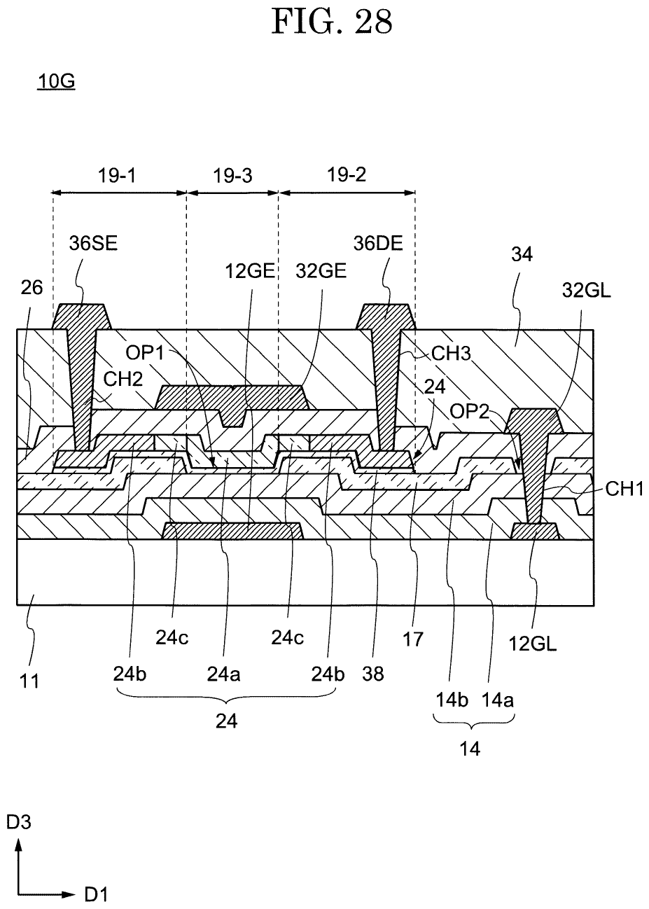

Next, semiconductor devices 10G to 10H, which have a partially different structure from the semiconductor device 10F, will be explained while referring to FIG. 28 to FIG. 31. Unless otherwise specified, the semiconductor devices 10G and 10H will be used to explain the case where Poly-OS is used as the oxide semiconductor layer 24 and aluminum oxide is used as the metal oxide film 17 and the metal oxide layer 18.

### Sixth Modification

FIG. 28 shows the semiconductor device 10G according to an embodiment of the present invention. The semiconductor device 10G has openings OP1 and OP2 in the metal oxide film 17. The metal oxide film 17 has the first region 19-1 and the second region 19-2, which sandwich the opening OP1. Specifically, the metal oxide layer includes the metal oxide layer 38 having a portion 1_1 (a first-first portion) corresponding to the first region 19-1, a portion 1_2 (a first-second portion) corresponding to the second region 19-2, and a portion 1_3 (a first-third portion) corresponding to the third region 19-3, and the metal oxide film 17 having an opening OP1 between the first region 19-1 and the second region 19-2, a metal oxide film 17 corresponding to the first region 19-1 and the second region 19-2, which is provided below the portion 1_1 and the portion 1_2. The manufacturing method for the semiconductor device 10G is the same as that for the semiconductor device 10F, so only the differences will be explained.

In the manufacturing method for the semiconductor device 10G, the difference from the manufacturing method for the semiconductor device 10F is the process in step S1209 shown in FIG. 25. In the manufacturing method for the semiconductor device 10G, the process in Step S1209 shown in FIG. 25 may be omitted, and the metal oxide film 37 may be etched using the oxide semiconductor layer 24 as a mask, and the metal oxide film 17 need not be etched. This allows the sides of the oxide semiconductor layer 24 and the metal oxide layer 38 to be arranged in a straight line.

In the semiconductor device 10G, IZO may be used in place of aluminum oxide as the metal oxide film 17. If IZO is used as the metal oxide film 17, it is sufficient to refer to the description of the oxide semiconductor film 43 of the semiconductor device 10E. If IZO is used as the metal oxide film 17, it is preferable to use aluminum oxide as the metal oxide layer 38. When using IZO as the metal oxide film 17, the content of indium in the oxide semiconductor layer 24 is greater than the content of indium in the metal oxide film 17. In the semiconductor device 10G, the oxide semiconductor material used in the oxide semiconductor layer 24 and the metal oxide film 17 may be different. In the manufacturing method of the semiconductor device 10G, when using IZO as the metal oxide film 17, it is sufficient to etch the oxide semiconductor film 21 in the process shown in step S1207 as shown in FIG. 25, and then to form the metal oxide layer 38 by etching only the metal oxide film 37 in the process shown in step S1209 after going through the process shown in step S1208.

### Seventh Modification

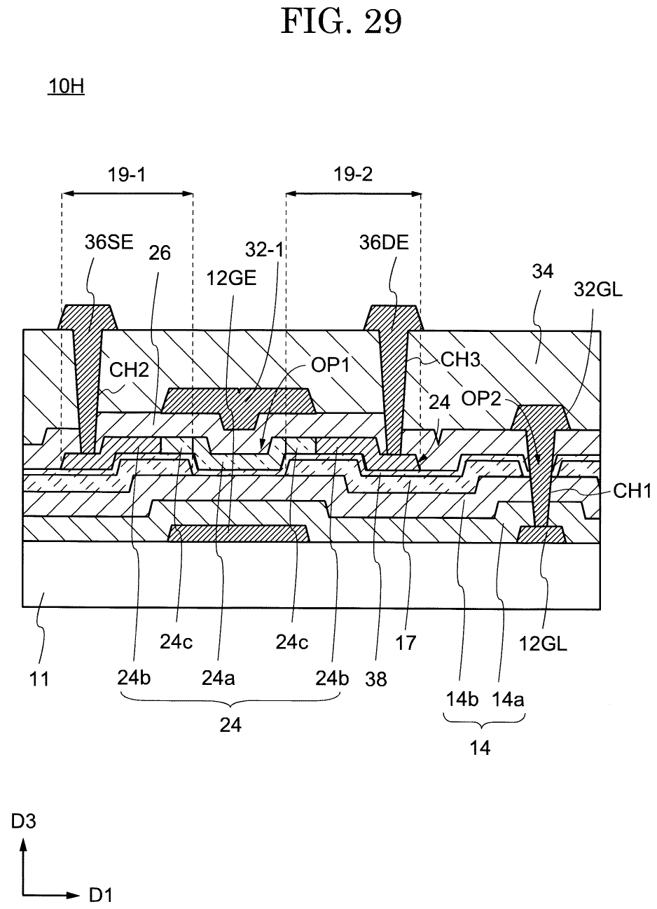

FIG. 29 shows the semiconductor device 10H according to an embodiment of the present invention. The semiconductor device 10H has the openings OP1 and OP2 in the metal oxide film 17. The first region 19-1 and the second region 19-2 are provided in the metal oxide film 17, sandwiching the opening OP1. The manufacturing method of the semiconductor device 10H is the same as that of the semiconductor device 10F, so only the differences will be explained.

In the manufacturing method for the semiconductor device 10H, the process at step S1209 in FIG. 25 differs from the manufacturing method for the semiconductor device 10F. In the manufacturing method for the semiconductor device 10, the process at step S1209 is omitted because the metal oxide film 17 does not need to be etched. Before forming the gate electrode 32GE and the gate wiring 32GL, contact holes CH1 are formed in the gate insulating film 26, the metal oxide film 37, and the gate insulating film 14. Since these contact holes include insulating films of different materials, it is not possible to form the contact holes CH1 in a single etching process. Therefore, it is necessary to process them using different etching methods.

As a first method for forming the contact hole CH1, the gate insulating film 26 may be etched by dry etching using a fluorine-based gas, and then the metal oxide film 37 inside the opening OP2 may be removed by wet etching, and the gate insulating film 14 may be etched by dry etching using a fluorine-based gas. As a second method, after etching the gate insulating film 26 using dry etching with a fluorine-based gas, the metal oxide film 37 inside the opening OP2 may be removed using dry etching with a chlorine-based gas, and the gate insulating film 14 may be etched using dry etching with a fluorine-based gas. As a third method, after etching the gate insulating film 26 and the metal oxide film 37 using dry etching with chlorine gas, the gate insulating film 14 may be etched using dry etching with fluorine gas. As a fourth method, after etching the gate insulating film 26 and the metal oxide film 37 using wet etching, the gate insulating film 14 may be etched using dry etching with fluorine gas. As a fifth method, the gate insulating film 26, the metal oxide film 37, and the gate insulating film 14 may be etched using dry etching with a fluorine-based gas. However, when etching the metal oxide film 37, it is preferable to increase the bias. As shown in FIG. 29, the metal oxide film 37 is also provided inside the opening OP2 of the metal oxide film 37.

In the semiconductor device 10H, IZO may be used in place of aluminum oxide as the metal oxide film 17. When IZO is used as the metal oxide film 17, it is preferable to use aluminum oxide as the metal oxide film 37.

### Eighth Modification

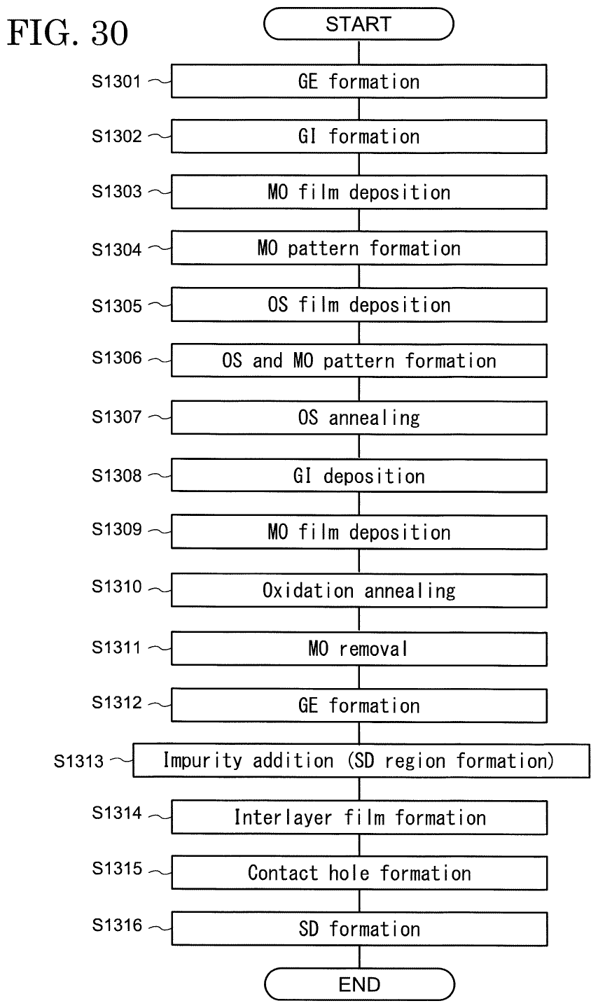

In the semiconductor devices 10, 10A to 10E, indium gallium zinc oxide (IGZO) may be used as the oxide semiconductor layer 24 instead of Poly-OS. For the cross-sectional configuration when using IGZO as the oxide semiconductor layer 24, it is sufficient to refer to the respective descriptions of the semiconductor devices 10, 10A to 10E. The crystallinity of IGZO may be amorphous or crystalline. When using IGZO as the oxide semiconductor layer 24, the manufacturing method for the semiconductor device in this case is shown in FIG. 30. In FIG. 30, the difference from the sequence diagram shown in FIG. 4 is in the processes of steps S1305, S1306, and S1308. IGZO has lower etching resistance than Poly-OS. Therefore, when considering the subsequent etching process, it is preferable to deposit the IGZO film in Step S1305 at a thickness of 10 nm or more and 50 nm or less, preferably 10 nm or more and 30 nm or less. In addition, it is difficult to etch the metal oxide film 17 using the oxide semiconductor layer 24 as a mask. Therefore, it is preferable to form the oxide semiconductor layer 46 and the metal oxide layer 18 by etching the metal oxide film 17 continuously after etching the oxide semiconductor film 21 using a resist mask in step S1306. The processes in steps S1307 to S1316 are the same as the processes in steps S1007, S1009 to S1017 shown in FIG. 4, so a detailed explanation is omitted.

### Ninth Modification

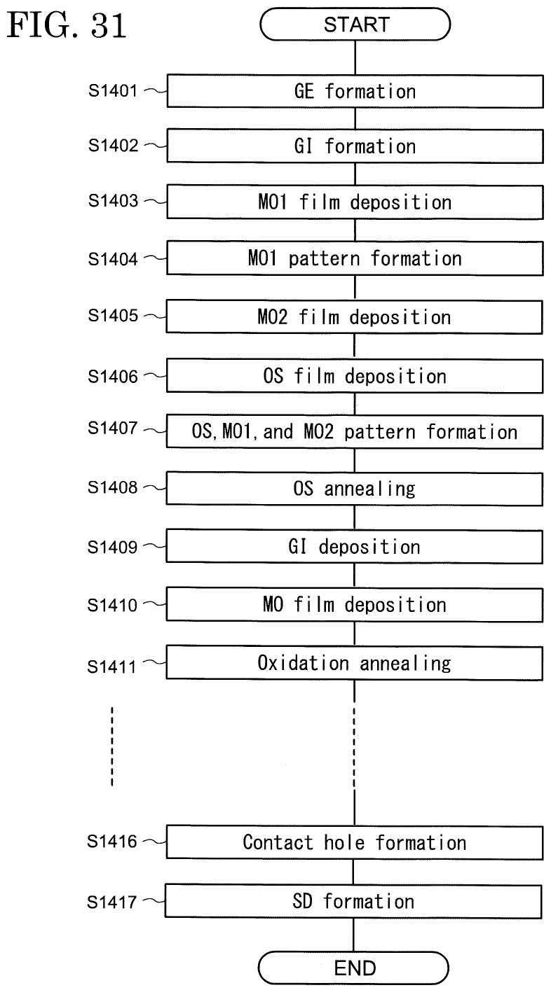

In the semiconductor device 10F, indium gallium zinc oxide (IGZO) may be used as the oxide semiconductor layer 24 instead of Poly-OS. For the cross-sectional configuration when using IGZO as the oxide semiconductor layer 24, refer to the description of the semiconductor device 10F. FIG. 31 shows the manufacturing method for the semiconductor device when using IGZO as the oxide semiconductor layer 24 in the semiconductor device 10F. In FIG. 31, the difference in the sequence diagram shown in FIG. 25 is the process from step S1406 to step S1407. As explained in the Eighth Modification, IGZO has lower etching resistance than Poly-OS. Therefore, considering the subsequent etching process, it is preferable to form an IGZO film with a thickness of 10 nm or more and 50 nm or less, preferably 10 nm or more and 30 nm or less, in Step S1406. In addition, it is difficult to etch the metal oxide films 17 and 37 using the oxide semiconductor layer 24 as a mask. Therefore, it is preferable to form the oxide semiconductor layer 22 and the metal oxide layers 18 and 38 by etching the metal oxide films 17 and 37 continuously after etching the oxide semiconductor film 21 using a resist mask in step S1407. The processes from Step S1408 to Step S1417 are the same as the processes from Step S1007 to Step S1017 shown in FIG. 25, so a detailed explanation is omitted.

### Tenth Modification

In the semiconductor device 10G, IZO may be used in place of Poly-OS as the oxide semiconductor layer 24. When IZO is used as the oxide semiconductor layer 24, aluminum oxide may be used as the metal oxide films 17 and 37. Alternatively, IZO may be used as the metal oxide film 17, and aluminum oxide may be used as the metal oxide layer 38. In the manufacturing method of the semiconductor device 10G, when using IZO as the oxide semiconductor layer 24, it is sufficient to etch both the oxide semiconductor film 21 and the metal oxide film 37 in the process shown in step S1207 of FIG. 25 to form the oxide semiconductor layer 22 and the metal oxide layer 38.

### Eleventh Modification

In the semiconductor device 10H, IZO may be used in place of Poly-OS as the oxide semiconductor layer 24. When IZO is used as the oxide semiconductor layer 24, aluminum oxide may be used as the metal oxide films 17 and 37. Alternatively, IZO may be used as the metal oxide film 17, and aluminum oxide may be used as the metal oxide layer 38. In the manufacturing method of the semiconductor device 10H, when using IZO as the oxide semiconductor layer 24, it is sufficient to etch only the oxide semiconductor film 21 and form the oxide semiconductor layer 22 and the metal oxide layer 38 in the process shown in step S1207 of FIG. 25.

### Twelfth Modification

In the semiconductor devices 10B to 10H, the width of the gate electrode 32GE in the direction D1 is described as being longer than the length of the first region 24a, but this is not limited to this. In the semiconductor devices 10B to 10H, the width of the gate electrode 32GE in the direction D1 may be shorter than the length of the first region 24a in the oxide semiconductor layer 24.

The various embodiments and variations described above as embodiments of the present invention may be combined and implemented as appropriate, as long as they do not contradict each other. In addition, the semiconductor devices and display devices of the various embodiments and variations may be used as the basis for the addition, deletion, or design change of components, or the addition, omission, or change of conditions, as appropriate, by a person skilled in the art, and as long as they have the gist of the present invention, they are also included in the scope of the present invention.

Even if the effects are different from the effects of the embodiments described above, if they are clear from the description in this document or can be easily predicted by a person skilled in the art, they are naturally considered to be brought about by the present invention.

What is claimed is:

1. A semiconductor device comprising:
an oxide insulating layer;
a metal oxide layer having a first region and a second region arranged on the oxide insulating layer and spaced apart from each other;
an oxide semiconductor layer arranged in contact with the first region and the second region;
a gate insulating layer arranged to cover the oxide semiconductor layer; and
a gate electrode arranged on the oxide semiconductor layer through the gate insulating layer,
wherein the oxide semiconductor layer includes a channel region overlapping the gate electrode, a source region and a drain region sandwiching the channel region, and the channel region is in contact with the oxide insulating film between the first region and the second region.

2. The semiconductor device according to claim 1, wherein
the metal oxide layer includes a first metal oxide layer that includes the first region and a second metal oxide layer that includes the second region.

3. The semiconductor device according to claim 1, wherein
the metal oxide layer has an opening between the first region and the second region.

4. The semiconductor device according to claim 1, wherein
a thickness of the metal oxide layer is larger than 5 nm and 10 nm or less.

5. The semiconductor device according to claim 1, wherein
the metal oxide layer is aluminum oxide or indium gallium zinc oxide.

6. The semiconductor device according to claim 5, wherein
an amount of indium contained in the oxide semiconductor layer is greater than an amount of indium contained in the indium gallium zinc oxide, when the metal oxide layer is indium gallium zinc oxide.

7. The semiconductor device according to claim 1, wherein
the oxide semiconductor layer has a polycrystalline structure.

8. A semiconductor device comprising:
an oxide insulating layer;
a metal oxide layer having a first region and a second region that are provided on the oxide insulating layer and are separated from each other, and a third region provided between the first region and the second region, an oxide semiconductor layer arranged in contact with the metal oxide layer;
a gate insulating layer arranged to cover the oxide semiconductor layer; and
a gate electrode arranged on the oxide semiconductor layer through the gate insulating layer,
wherein the oxide semiconductor layer includes a channel region overlapping the gate electrode, and a source region and a drain region sandwiching the channel region,
the source region is in contact with the first region, the drain region is in contact with the second region, and the channel region is in contact with the third region, and
a thickness of the metal oxide layer in the first region and the second region is larger than a thickness of the metal oxide layer in the third region.

9. The semiconductor device according to claim 8, wherein
the metal oxide layer is aluminum oxide.

10. The semiconductor device according to claim 8, wherein
the metal oxide layer includes a first metal oxide layer having a first-first portion corresponding to the first region, a first-second portion corresponding to the second region, and a first-third portion corresponding to the third region, a second metal oxide layer located under the first-first portion and corresponding to the first region, and a third metal oxide layer located under the first-second portion and corresponding to the second region.

11. The semiconductor device according to claim 10, wherein
a thickness of the first metal oxide layer is 5 nm or less, and
a thicknesses of the second oxide layer and third metal oxide layer are larger than 5 nm and 10 nm or less, respectively.

12. The semiconductor device according to claim 10, wherein
the first metal oxide layer is aluminum oxide, and
the second metal oxide layer and third metal oxide layer are aluminum oxide or indium gallium zinc oxide.

13. The semiconductor device according to claim 12, wherein
an amount of indium contained in the oxide semiconductor layer is greater than an amount of indium contained in the second and third metal oxide layers, when the second and third metal oxide layers are indium gallium zinc oxide.

14. The semiconductor device according to claim 8, wherein
the metal oxide layer includes a first metal oxide layer that has a first-first portion corresponding to the first region, a first-second portion corresponding to the second region, and a first-third portion corresponding to the third region, and a second metal oxide layer that has an opening between the first region and the second region, is located below the first-first portion and the first-second portion, and corresponds to the first region and the second region.

15. The semiconductor device according to claim 10, wherein
a thickness of the first metal oxide layer is 5 nm or less, and
a thickness of the second metal oxide layer is larger than 5 nm and 10 nm or less.

16. The semiconductor device according to claim 15, wherein
the first metal oxide layer is aluminum oxide, and
the second metal oxide layer is aluminum oxide or indium gallium zinc oxide.

17. The semiconductor device according to claim 16, wherein
an amount of indium contained in the oxide semiconductor layer is greater than an amount of indium contained in the second metal oxide layer.

18. The semiconductor device according to claim 16, wherein
the oxide semiconductor layer has a polycrystalline structure.
